(19) United States
(12) Patent Application Publication
(10) Pub. No.: US 2025/0004374 A1
(43) Pub. Date: Jan. 2, 2025

(54) ACTINIC RAY-SENSITIVE OR RADIATION-SENSITIVE RESIN COMPOSITION, RESIST FILM, PATTERN FORMING METHOD, METHOD FOR PRODUCING ELECTRONIC DEVICE, AND ELECTRONIC DEVICE

(71) Applicant: FUJIFILM Corporation, Tokyo (JP)

(72) Inventors: Michihiro SHIRAKAWA, Haibara-gun (JP); Satomi Takahashi, Haibara-gun (JP)

(73) Assignee: FUJIFILM Corporation, Tokyo (JP)

(21) Appl. No.: 18/827,190

(22) Filed: Sep. 6, 2024

Related U.S. Application Data
(63) Continuation of application No. PCT/JP2023/010042, filed on Mar. 15, 2023.

(30) Foreign Application Priority Data
Mar. 25, 2022 (JP) 2022-050127

(51) Int. Cl. G03F 7/039; G03F 7/004; G03F 7/32; G03F 7/38; G03F 7/40

(52) U.S. Cl. CPC G03F 7/039; G03F 7/0045; G03F 7/325; G03F 7/38; G03F 7/40

(57) ABSTRACT

The present invention provides an actinic ray-sensitive or radiation-sensitive resin composition with high DOF performance. An actinic ray-sensitive or radiation-sensitive resin composition according to the present invention includes a resin that includes a repeating unit represented by a formula (I) and a repeating unit represented by a formula (II) and has a main chain that is cleaved by exposure, and an ionic compound represented by a formula (III), and the resin satisfies predetermined requirements,

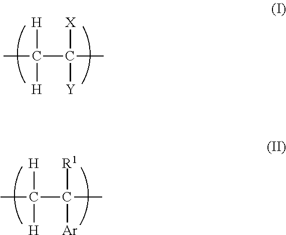

### CROSS-REFERENCE TO RELATED APPLICATIONS

This application is a Continuation of PCT International Application No. PCT/JP2023/010042 filed on Mar. 15, 2023, which claims priority under 35 U.S.C. § 119(a) to Japanese Patent Application No. 2022-050127 filed on Mar. 25, 2022. The above applications are hereby expressly incorporated by reference, in their entirety, into the present application.

### BACKGROUND OF THE INVENTION

### 1. Field of the Invention

The present invention relates to an actinic ray-sensitive or radiation-sensitive resin composition, a resist film, a pattern forming method, a method for producing an electronic device, and an electronic device.

### 2. Description of the Related Art

After a resist for a KrF excimer laser (248 nm), a pattern forming method utilizing chemical amplification has been used to compensate for a decrease in sensitivity due to light absorption. For example, in a positive chemical amplification method, first, a photoacid generator in an exposed portion is decomposed by photoirradiation and produces an acid. In a process of post exposure bake (PEB) or the like, the catalytic action of the produced acid changes an alkali-insoluble group of a resin in an actinic ray-sensitive or radiation-sensitive resin composition to an alkali-soluble group or the like and thereby changes solubility in a developer. Subsequently, development is performed, for example, using a basic aqueous solution. This removes the exposed portion and forms a desired pattern.

To miniaturize a semiconductor element, the wavelength of an exposure light source has been shortened, and the numerical aperture of a projection lens has been increased (higher NA). At present, an exposure apparatus using an ArF excimer laser with a wavelength of 193 nm as a light source has been developed. In recent years, a pattern forming method using extreme ultraviolet (EUV) and an electron beam (EB) as a light source has also been studied.

Under such circumstances, various configurations have been proposed as actinic ray-sensitive or radiation-sensitive resin compositions.

For example, WO2021-153466A discloses, as a positive resist composition that can form a pattern with very high resolution in the formation of an ultrafine pattern (for example, 40 nm or less), “a positive resist composition that contains (A) an ionic compound and (B) a resin that has a repeating unit (b1) having an interactive group capable of interacting with an ionic group in the ionic compound and has a main chain that is decomposed by irradiation with X-rays, an electron beam, or extreme ultraviolet”.

### SUMMARY OF THE INVENTION

On the other hand, in recent years, further improvement in depth of focus (DOF) performance has been demanded.

The present inventors have studied the formation of a pattern using a resist composition described in WO2021-153466A and have found that the DOF performance does not satisfy a higher performance level required in recent years, and there is room for further improvement.

Accordingly, it is an object of the present invention to provide an actinic ray-sensitive or radiation-sensitive resin composition with high DOF performance.

It is also an object of the present invention to provide a resist film, a pattern forming method, a method for producing an electronic device, and an electronic device which are related to the actinic ray-sensitive or radiation-sensitive resin composition.

As a result of extensive studies to solve these problems, the present inventors have found that the problems can be solved by the following configurations.

[1] An actinic ray-sensitive or radiation-sensitive resin composition including:
a resin that includes a repeating unit represented by a formula (I) described later and a repeating unit represented by a formula (II) described later and has a main chain that is cleaved by exposure; and
an ionic compound represented by a formula (III) described later,
wherein the resin satisfies at least one of a requirement 1 or a requirement 2 described later.

[2] The actinic ray-sensitive or radiation-sensitive resin composition according to [1], wherein a requirement 3 described later is satisfied.

[3] The actinic ray-sensitive or radiation-sensitive resin composition according to [1] or [2], wherein a requirement 4 described later is satisfied.

[4] The actinic ray-sensitive or radiation-sensitive resin composition according to any one of [1] to [3], wherein a total amount of a repeating unit having a group represented by a formula (IV) and a repeating unit having a carboxy group in the resin is 0.30 mmol/g or more based on a total solid content of the actinic ray-sensitive or radiation-sensitive resin composition.

[5] The actinic ray-sensitive or radiation-sensitive resin composition according to any one of [1] to [4], wherein the resin has a weight-average molecular weight of 20,000 or more.

[6] The actinic ray-sensitive or radiation-sensitive resin composition according to any one of [1] to [5], wherein the resin has a weight-average molecular weight of 30,000 or more.

[7] The actinic ray-sensitive or radiation-sensitive resin composition according to any one of [1] to [6], wherein the resin has a polydispersity of 2.0 or less.

[8] The actinic ray-sensitive or radiation-sensitive resin composition according to any one of [1] to [7], wherein the resin has a polydispersity of 1.7 or less.

[9] The actinic ray-sensitive or radiation-sensitive resin composition according to any one of [1] to [8], wherein an ionic compound content ranges from 0.10 to 1.00 mmol/g based on the total solid content of the actinic ray-sensitive or radiation-sensitive resin composition.

[10] A resist film formed by using the actinic ray-sensitive or radiation-sensitive resin composition according to any one of [1] to [9].

[11] A pattern forming method including:
a step 1 of forming a resist film on a substrate using the actinic ray-sensitive or radiation-sensitive resin composition according to any one of [1] to [9];
a step 2 of exposing the resist film; and
a step 3 of developing the exposed resist film using a developer including an organic solvent to form a pattern.

[12] The pattern forming method according to [11], further having a step 4 of washing the pattern using a rinse liquid including an organic solvent after the step 3.

[13] The pattern forming method according to [11], wherein
when the pattern forming method does not have the step 4 of washing the pattern using the rinse liquid including the organic solvent after the step 3, the developer includes two or more organic solvents, and
when the pattern forming method has the step 4 of washing the pattern using the rinse liquid including the organic solvent after the step 3, at least one of the developer or the rinse liquid includes two or more organic solvents.

[14] The pattern forming method according to [13], wherein
the two or more organic solvents include a first organic solvent and a second organic solvent,
the first organic solvent has a higher boiling point than the second organic solvent, and
the first organic solvent has a higher C log P value than the second organic solvent.

[15] A method for producing an electronic device, including the pattern forming method according to any one of [11] to [14].

[16] An electronic device produced by the method for producing an electronic device according to [15].

The present invention can provide an actinic ray-sensitive or radiation-sensitive resin composition with high DOF performance.

The present invention can also provide a resist film, a pattern forming method, a method for producing an electronic device, and an electronic device which are related to the actinic ray-sensitive or radiation-sensitive resin composition.

### DESCRIPTION OF THE PREFERRED EMBODIMENTS

The present invention is described in detail below.

Although the constituent features described below may be described on the basis of typical embodiments of the present invention, the present invention is not limited to such embodiments.

Unless otherwise specified, the term “substituent”, as used herein, is preferably a monovalent substituent.

The term “organic group”, as used herein, refers to a group including at least one carbon atom.

The term “actinic ray” or “radiation”, as used herein, refers to, for example, an emission-line spectrum of a mercury lamp, far-ultraviolet light represented by an excimer laser, extreme ultraviolet (EUV), X-rays, an electron beam (EB), or the like. The term “light”, as used herein, refers to an actinic ray or radiation.

Unless otherwise specified, the term “exposure”, as used herein, includes, for example, not only exposure to an emission-line spectrum of a mercury lamp, far-ultraviolet light represented by an excimer laser, extreme ultraviolet, X-rays, or the like, but also drawing with a particle beam, such as an electron beam or an ion beam.

The term “to”, as used herein, means that numerical values described before and after the term are included as a lower limit and an upper limit.

The bonding direction of a divalent group described in the present specification is not limited unless otherwise specified. For example, when Y in a compound represented by the general formula “X—Y—Z” is —COO—, Y may be —CO—O— or —O—CO—. The compound may be “X—CO—O—Z” or “X—O—CO—Z”.

The term “ppm”, as used herein, refers to “parts-per-million (10⁻⁶)”, “ppb” refers to “parts-per-billion (10⁻⁹)”, and “ppt” refers to “parts-per-trillion (10⁻¹²)”.

In the present specification, the weight-average molecular weight (Mw), the number-average molecular weight (Mn), and the polydispersity (also referred to as molecular weight distribution) (Mw/Mn) of a resin are defined as polystyrene equivalent values by GPC measurement using a GPC (Gel Permeation Chromatography) apparatus (HLC-8120GPC manufactured by Tosoh Corporation) (solvent: tetrahydrofuran, flow rate (sample injection volume): 10 μL, column: TSK gel Multipore HXL-M manufactured by Tosoh Corporation, column temperature: 40° C., flow rate: 1.0 mL/min, detector: refractive index detector)).

The C log P value is calculated using the program “C LOG P” available from Daylight Chemical Information System, Inc. This program provides a “calculated log P” value calculated by the fragment approach of Hansch, Leo (see the following literature). The fragment approach is based on the chemical structure of a compound, where the chemical structure is divided into substructures (fragments), and the log P contributions assigned to the fragments are summed to estimate the log P value of the compound. Details thereof are described in the following literature. In the present specification, C log P values calculated using a program C LOG P v4.82 are used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990 C. Hansch & A. J. Leo. SUbstituent Constants For Correlation Analysis in Chemistry and Biology. John Wiley & Sons. A. J. Leo. Calculating log Poct from structure. Chem. Rev., 93, 1281-1306, 1993.

log P means a common logarithm of a partition coefficient P and is a physical property representing the distribution of an organic compound as a quantitative numerical value in equilibrium of a two phase system of oil (typically 1-octanol) and water. log P is represented by the following formula:

log P=log(Coil/Cwater)

In the formula, Coil denotes the molar concentration of the compound in the oil phase, and Cwater denotes the molar concentration of the compound in the aqueous phase.

An increase in the value of log P in the positive direction with respect to 0 results in an increase in oil solubility. An increase in the absolute value of log P in the negative direction with respect to 0 results in an increase in water solubility. Thus, log P has a negative correlation with the water solubility of an organic compound and is widely used as a parameter for estimating the hydrophilicity and hydrophobicity of an organic compound.

In the present specification, a halogen atom is, for example, a fluorine atom, a chlorine atom, a bromine atom, or an iodine atom.

In the present specification, a solid component means a component that forms a resist film, and does not include a solvent. A component, even in a liquid state, that forms a resist film is regarded as a solid component.

### [Actinic Ray-Sensitive or Radiation-Sensitive Resin Composition]

An actinic ray-sensitive or radiation-sensitive resin composition (hereinafter also referred to as a “resist composition”) according to the present invention includes a resin (hereinafter also referred to as a “resin (C)”) that includes a repeating unit represented by the formula (I) described later and a repeating unit represented by the formula (II) described later and has a main chain that is cleaved by exposure, and an ionic compound represented by a formula (III), wherein the resin satisfies at least one of a requirement 1 or a requirement 2 described later.

While the mechanism by which the resist composition with the described configuration addresses the issues of the present invention is not entirely clear, the present inventors propose the following explanation.

In WO2021-153466A, an ionic compound and a main-chain-scission type polymer form an association state by electrostatic interaction, and a resist film therefore has a low dissolution rate in a developer. When the resist film is exposed, the association state is removed, and a difference in dissolution rate in a developer (so-called dissolution contrast) is generated between an unexposed portion and an exposed portion.

On the other hand, the present inventors have found that, in the prior literature as described above, a side reaction occurs between a resin (or a product produced by cleavage of the resin) and an ionic compound at the time of exposure, and the resin may be three-dimensionally crosslinked and reduce the dissolution rate in a developer. Such a side reaction results in a decrease in the dissolution contrast and can be a cause of degradation in the DOF performance.

On the other hand, in the resist composition according to the present invention, it has been found that desired effects can be achieved when the resin satisfies at least one of the requirement 1 or the requirement 2 described later. More specifically, when the resin satisfies at least one of the requirement 1 or the requirement 2 described later, the resin has a predetermined polar group. This polar group interacts with an ionic compound and increases the dissolution contrast, and the side reaction is less likely to proceed. This can reduce the decrease in the dissolution contrast and results in improved DOF performance. The reason why the side reaction is less likely to proceed is presumed that a group represented by the formula (IV) and the carboxy group trap a radical or the like which may be generated during the side reaction.

When an anion (D⁻) in the ionic compound is an anion formed by dissociation of a proton from a carboxy group in a specific compound having the carboxy group and not including an aromatic ring, and a compound produced by addition of a proton to the anion (D⁻) in the ionic compound has a C log P value of more than 3.00, the interaction between the resin and the ionic compound is less likely to occur. Thus, when the anion (D⁻) in the ionic compound is an anion formed by dissociation of a proton from a carboxy group in a specific compound having the carboxy group and not including an aromatic ring, and a compound produced by addition of a proton to the anion (D⁻) in the ionic compound has a C log P value of 3.00 or less, it is thought that a stable association state can be formed between the resin and the ionic compound and improve the dissolution contrast.

Higher DOF performance is also referred to as greater advantages of the present invention.

The components of the resist composition according to the present invention are described below.

[Resin with Main Chain that is Cleaved by Exposure]

The resist composition includes a resin that includes a repeating unit represented by the formula (I) and a repeating unit represented by the formula (II) and has a main chain that is cleaved by exposure.

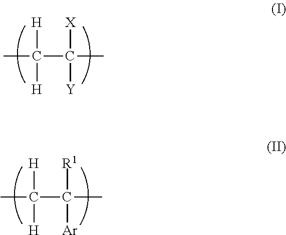

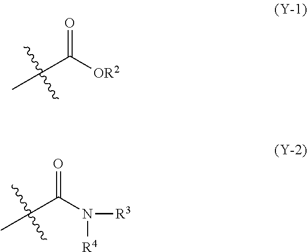

In the formula (I), X denotes a halogen atom. The halogen atom is, for example, a fluorine atom, a chlorine atom, a bromine atom, or an iodine atom and is, in terms of greater advantages of the present invention, preferably a chlorine atom, a bromine atom, or an iodine atom, more preferably a chlorine atom or an iodine atom, particularly preferably a chlorine atom.

In the formula (I), Y denotes a group represented by the formula (Y-1) or a group represented by the formula (Y-2). In the formula (Y-1) and in the formula (Y-2), a wavy line portion represents a binding position.

When Y in the formula (I) is a group represented by the formula (Y-1) and when Y in the formula (I) is a group represented by the formula (Y-2), they are represented by the following repeating units, respectively.

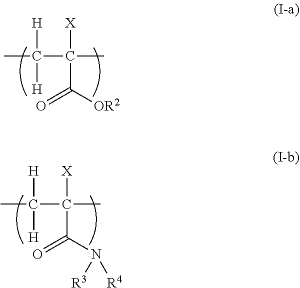

In the formula (Y-1), R² denotes a hydrogen atom or a monovalent organic group.

The monovalent organic group denoted by R² is, for example, but not limited to, an alkyl group optionally having a substituent, a monovalent aromatic group optionally having a substituent, an aralkyl group optionally having a substituent, or the like.

The substituent that each of the alkyl group, the monovalent aromatic group, and the aralkyl group may have (hereinafter also referred to as a “substituent T”) may be a halogen atom, such as a fluorine atom, a chlorine atom, a bromine atom, or an iodine atom; an alkoxy group, such as a methoxy group, an ethoxy group, or a tert-butoxy group; an aryloxy group, such as a phenoxy group or a p-tolyloxy group; an alkoxycarbonyl group, such as a methoxycarbonyl group, a butoxycarbonyl group, or a phenoxycarbonyl group; an acyloxy group, such as an acetoxy group, a propionyloxy group, or a benzoyloxy group; an acyl group, such as an acetyl group, a benzoyl group, an isobutyryl group, an acryloyl group, a methacryloyl group, or a methoxalyl group; an alkylsulfanyl group, such as a methylsulfanyl group or a tert-butylsulfanyl group; an arylsulfanyl group, such as a phenylsulfanyl group or a p-tolylsulfanyl group; an alkyl group; an aryl group; a heteroaryl group; a hydroxy group; a carboxy group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group; a nitro group; the group represented by the formula (IV) described later, or a combination thereof.

Among these, the substituent is preferably a group selected from the group consisting of the group represented by the formula (IV) described later and a carboxy group (hereinafter also referred to as a “specific functional group”) in terms of greater advantages of the present invention. Thus, the monovalent organic group denoted by R² may be a monovalent organic group including the specific functional group, and this case corresponds to satisfying the requirement 1 described later.

The case where R² is a hydrogen atom also corresponds to satisfying the requirement 1 described later.

The monovalent organic group denoted by R² is preferably an alkyl group optionally having a substituent or a monovalent aromatic group optionally having a substituent in terms of greater advantages of the present invention.

The alkyl group may be linear, branched, or cyclic and is, for example, a linear or branched alkyl group, such as a methyl group, an ethyl group, a n-propyl group, an i-propyl group, a n-butyl group, a t-butyl group, or a n-hexyl group; a monocyclic cycloalkyl group (cyclic alkyl group), such as a cyclopentyl group or a cyclohexyl group; a polycyclic cycloalkyl group, such as a norbornyl group, a tetracyclodecanyl group, a tetracyclododecanyl group, or an adamantyl group, or the like.

Among these, the alkyl group is preferably a linear alkyl group. The number of carbon atoms in the linear alkyl group preferably ranges from 1 to 20, more preferably 1 to 6, still more preferably 1 or 2, most preferably 1. When the alkyl group has a substituent, the alkyl group preferably has the substituent at a terminal of the alkyl group. The substituent that the alkyl group may have is as described above and is, for example, any of the groups presented as examples of the substituent T, preferably a specific functional group.

The monovalent aromatic group may be, but is not limited to, an aryl group or a heteroaryl group.

The monovalent aromatic group may be monocyclic or polycyclic, and the number of ring atoms preferably ranges from 6 to 15, more preferably 6 to 10.

Among these, the monovalent aromatic group is preferably a phenyl group, a naphthyl group, or an anthracenyl group, more preferably a phenyl group or a naphthyl group, still more preferably a phenyl group.

When the phenyl group has a substituent, the phenyl group preferably has the substituent at the para position of the phenyl group. The substituent that the monovalent aromatic group may have is as described above. The monovalent aromatic group may have two hydroxy groups as substituents and constitute the group represented by the formula (IV) described later. The monovalent aromatic group may also have a carboxy group as a substituent.

In the formula (Y-2), R³ and R⁴ each independently denote a hydrogen atom or a monovalent organic group.

The monovalent organic group denoted by R³ or R⁴ is, for example, but not limited to, an alkyl group optionally having a substituent, a monovalent aromatic group optionally having a substituent, an aralkyl group optionally having a substituent, or the like.

The substituent that the alkyl group, the monovalent aromatic group, and the aralkyl group may have may be, but is not limited to, any of the groups presented as examples of the substituent T described above. Among these, in terms of greater advantages of the present invention, the monovalent organic group denoted by R³ or R⁴ is preferably a monovalent organic group including a specific functional group, and this case corresponds to satisfying the requirement 1.

Among these, in terms of greater advantages of the present invention, the monovalent organic group denoted by R³ or R⁴ is preferably an alkyl group optionally having a substituent.

The alkyl group may be linear, branched, or cyclic and is, for example, a linear or branched alkyl group, such as a methyl group, an ethyl group, a n-propyl group, an i-propyl group, a n-butyl group, a t-butyl group, or a n-hexyl group; a monocyclic cycloalkyl group, such as a cyclopentyl group or a cyclohexyl group; a polycyclic cycloalkyl group, such as a norbornyl group, a tetracyclodecanyl group, a tetracyclododecanyl group, or an adamantyl group, or the like.

Among these, the alkyl group is preferably a linear alkyl group. The number of carbon atoms in the linear alkyl group preferably ranges from 1 to 20, more preferably 1 to 6, still more preferably 1 or 2, most preferably 1. When the alkyl group has a substituent, the alkyl group preferably has the substituent at a terminal of the alkyl group. The substituent that the alkyl group may have may be any of the groups presented as examples of the substituent T.

The amount of the repeating unit represented by the formula (I) preferably ranges from 20% to 80% by mole, more preferably 40% to 70% by mole, still more preferably 50% to 70% by mole, with respect to all repeating units in the resin (C).

In the formula (II), R¹ denotes an alkyl group optionally having a substituent, and Ar denotes a monovalent aromatic group optionally having a substituent.

The alkyl group denoted by R¹ may be linear, branched, or cyclic and is, for example, a linear or branched alkyl group, such as a methyl group, an ethyl group, a n-propyl group, an i-propyl group, a n-butyl group, a t-butyl group, or a n-hexyl group; a monocyclic cycloalkyl group, such as a cyclopentyl group or a cyclohexyl group; a polycyclic cycloalkyl group, such as a norbornyl group, a tetracyclodecanyl group, a tetracyclododecanyl group, or an adamantyl group, or the like.

Among these, the alkyl group is preferably a linear alkyl group, more preferably a linear alkyl group with 1 to 5 carbon atoms, still more preferably a methyl group or an ethyl group, particularly preferably a methyl group.

The substituent that the alkyl group may have may be, but is not limited to, any of the groups presented as examples of the substituent T.

The monovalent aromatic group denoted by Ar may be, but is not limited to, an aryl group or a heteroaryl group.

The monovalent aromatic group may be monocyclic or polycyclic, and the number of ring atoms preferably ranges from 6 to 15, more preferably 6 to 10.

Among these, the monovalent aromatic group is preferably a phenyl group, a naphthyl group, or an anthracenyl group, more preferably a phenyl group or a naphthyl group, still more preferably a phenyl group.

When the phenyl group has a substituent, the phenyl group preferably has the substituent at the para position of the phenyl group. The number of substituents is preferably, but not limited to, 1 to 4, more preferably 1 to 2.

The substituent that the monovalent aromatic group may have may be any of the groups presented as examples of the substituent T described above. The monovalent aromatic group may have two hydroxy groups as substituents and constitute a group represented by the formula (IV) described later. The monovalent aromatic group may also have a carboxy group as a substituent. This case corresponds to satisfying the requirement 1 described later.

The amount of the repeating unit represented by the formula (II) preferably ranges from 20% to 80% by mole, more preferably 30% to 60% by mole, still more preferably 30% to 50% by mole, with respect to all repeating units in the resin (C).

The total amount of the repeating unit represented by the formula (I) and the repeating unit represented by the formula (II) preferably ranges from 80% to 100% by mole, more preferably 90% to 100% by mole, still more preferably 95% to 100% by mole, with respect to all repeating units in the resin (C).

The resin (C) may include another repeating unit that does not correspond to both the repeating unit represented by the formula (I) and the repeating unit represented by the formula (II).

For example, the resin (C) may have a repeating unit having the group represented by the formula (IV) or a carboxy group (hereinafter also referred to simply as a “unit with a specific functional group”), which is different from both the repeating unit represented by the formula (I) and the repeating unit represented by the formula (II), and this case corresponds to satisfying the requirement 2 described later.

The resin (C) satisfies at least one of the following requirement 1 or requirement 2. The resin (C) preferably satisfies the requirement 1 in terms of greater advantages of the present invention.

Requirement 1: at least one repeating unit selected from the group consisting of the repeating unit represented by the formula (I) and the repeating unit represented by the formula (II) has a group represented by the formula (IV) or a carboxy group.

Requirement 2: the resin further includes another repeating unit different from both the repeating unit represented by the formula (I) and the repeating unit represented by the formula (II), and the other repeating unit has the group represented by the formula (IV) or a carboxy group.

In the formula (IV), * denotes a binding position.

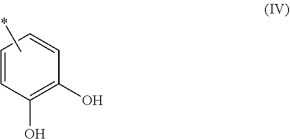

The requirement 1, in other words, provides that the resin (C) has at least one repeating unit selected from the group consisting of a repeating unit represented by the formula (I) that has the group represented by the formula (IV) or a carboxy group (hereinafter also referred to simply as a “specific unit 1”) and a repeating unit represented by the formula (II) that has the group represented by the formula (IV) or a carboxy group (hereinafter also referred to simply as a “specific unit 2”).

The specific unit 1 may be any of the following units 1-1 to 1-3:
Unit 1-1: a repeating unit represented by the formula (I) in which Y is a group represented by the formula (Y-1) and R² is a monovalent organic group including the group represented by the formula (IV) or including a carboxy group
Unit 1-2: a repeating unit represented by the formula (I) in which Y is a group represented by the formula (Y-1) and R² is a hydrogen atom
Unit 1-3: a repeating unit represented by the formula (I) in which Y is a group represented by the formula (Y-2) and at least one of R³ or R⁴ is a monovalent organic group including the group represented by the formula (IV) or including a carboxy group

The monovalent organic group including the group represented by the formula (IV) or including a carboxy group may be the group represented by the formula (IV) itself, an alkyl group having the group represented by the formula (IV), an alkyl group having a carboxy group, or an aryl group having a carboxy group.

The specific unit 2 may be a unit 2-1, a unit 2-2, or a unit 2-3.
Unit 2-1: a repeating unit represented by the formula (II) in which Ar is the group represented by the formula (IV)
Unit 2-2: a repeating unit represented by the formula (II) in which Ar is a monovalent aromatic group having a carboxy group
Unit 2-3: a repeating unit represented by the formula (II) in which R¹ is an alkyl group having the group represented by the formula (IV) or having a carboxy group

The phrase “Ar is the group represented by the formula (IV)” means that Ar has two hydroxy groups as substituents and Ar itself constitutes the group represented by the formula (IV).

The requirement 2, in other words, provides that the resin (C) has a unit with a specific functional group.

The total amount of the repeating unit having the group represented by the formula (IV) and the repeating unit having a carboxy group in the resin (C) is, but not limited to, often 0.20 mmol/g or more, and, in terms of greater advantages of the present invention, preferably 0.30 mmol/g or more, more preferably 1.00 mmol/g or more, still more preferably 1.50 mmol/g or more, based on the total solid content of the composition. The upper limit is, but not limited to, often 4.00 mmol/g or less, more often 3.00 mmol/g or less.

For example, when the resin (C) satisfies the requirement 1 but does not satisfy the requirement 2, the total amount of the repeating unit having the group represented by the formula (IV) and the repeating unit having a carboxy group in the resin (C) corresponds to the total amount of the specific unit 1 and the specific unit 2 (more specifically, the total amount of the units 1-1 to 1-3 and the units 2-1 to 2-3).

When the resin (C) does not satisfy the requirement 1 but satisfies the requirement 2, the total amount of the repeating unit having the group represented by the formula (IV) and the repeating unit having a carboxy group in the resin (C) corresponds to the amount of the unit with a specific functional group.

Furthermore, when the resin (C) satisfies the requirements 1 and 2, the total amount of the repeating unit having the group represented by the formula (IV) and the repeating unit having a carboxy group in the resin (C) corresponds to the total amount of the specific unit 1, the specific unit 2, and the unit with a specific functional group.

When the resin (C) includes the specific unit 1, the specific unit 1 content of the resin (C) is, but not limited to, preferably 5% to 55% by mole, more preferably 5% to 45% by mole, with respect to all repeating units in the resin (C), in terms of greater advantages of the present invention.

When the resin (C) includes the specific unit 2, the specific unit 2 content of the resin (C) is, but not limited to, preferably 5% to 55% by mole, more preferably 5% to 45% by mole, with respect to all repeating units in the resin (C), in terms of greater advantages of the present invention.

The amount of the repeating unit having the group represented by the formula (IV) in the resin (C) is, but not limited to, preferably 0.10 to 4.00 mmol/g, more preferably 0.20 to 3.00 mmol/g, based on the total solid content of the composition, in terms of greater advantages of the present invention.

The repeating unit having the group represented by the formula (IV) may be a repeating unit represented by the formula (I) having the group represented by the formula (IV) (hereinafter also referred to as a “specific unit A1”), a repeating unit represented by the formula (II) having the group represented by the formula (IV) (hereinafter also referred to as a “specific unit A2”), or a repeating unit different from both the specific unit A1 and the specific unit A2 and having the group represented by the formula (IV).

The specific unit A1 may be a repeating unit represented by the formula (I) in which Y is a group represented by the formula (Y-1) and R² is a monovalent organic group including the group represented by the formula (IV), or a repeating unit represented by the formula (I) in which Y is a group represented by the formula (Y-2) and at least one of R³ or R⁴ is a monovalent organic group including the group represented by the formula (IV).

The monovalent organic group including the group represented by the formula (IV) may be the group represented by the formula (IV) itself or an alkyl group having the group represented by the formula (IV).

The specific unit A2 may be a repeating unit represented by the formula (II) in which Ar is the group represented by the formula (IV), or a repeating unit represented by the formula (II) in which R¹ is an alkyl group having the group represented by the formula (IV).

The amount of the repeating unit having a carboxy group in the resin (C) is, but not limited to, preferably 0.10 to 3.00 mmol/g, more preferably 0.10 to 2.00 mmol/g, based on the total solid content of the composition, in terms of greater advantages of the present invention.

The repeating unit having a carboxy group may be a repeating unit represented by the formula (I) having a carboxy group (hereinafter also referred to as a “specific unit B1”), a repeating unit represented by the formula (II) having a carboxy group (hereinafter also referred to as a “specific unit B2”), or a repeating unit different from both the specific unit B1 and the specific unit B2 and having a carboxy group.

The specific unit B1 may be a repeating unit represented by the formula (I) in which Y is a group represented by the formula (Y-1) and R² is a monovalent organic group including a carboxy group, a repeating unit represented by the formula (I) in which Y is a group represented by the formula (Y-1) and R² is a hydrogen atom, or a repeating unit represented by the formula (I) in which Y is a group represented by the formula (Y-2) and at least one of R³ or R⁴ is a monovalent organic group including a carboxy group.

The monovalent organic group including a carboxy group may be an alkyl group having a carboxy group or an aryl group having a carboxy group.

The specific unit B2 may be a repeating unit represented by the formula (II) in which Ar is a monovalent aromatic group having a carboxy group, or a repeating unit represented by the formula (II) in which R¹ is an alkyl group having a carboxy group.

The resin (C) may include both the specific unit 1 and the specific unit 2.

The resin (C) may include a repeating unit represented by the formula (I) other than the specific unit 1 or may include a repeating unit represented by the formula (II) other than the specific unit 2.

The resin (C) may include another repeating unit other than the repeating units described above. For example, a repeating unit having only one phenolic hydroxy group is mentioned.

In the resin (C), the amount of the repeating unit having only one phenolic hydroxy group is preferably 20% by mole or less, more preferably 10% by mole or less, still more preferably 5% by mole or less, particularly preferably 0% by mole, with respect to all repeating units in the resin (C).

The weight-average molecular weight (Mw) of the resin (C) is preferably, but not limited to, 15,000 or more, more preferably 20,000 or more, still more preferably 30,000 or more, in terms of greater advantages of the present invention. The upper limit is preferably, but not limited to, 200,000 or less, more preferably 150,000 or less.

The polydispersity of the resin (C) is preferably, but not limited to, 2.5 or less, more preferably 2.0 or less, still more preferably 1.7 or less, in terms of greater advantages of the present invention. The lower limit may be, but is not limited to, 1.0 or more.

The resin (C) content is preferably, but not limited to, 40% to 99% by mass, more preferably 60% to 97% by mass, still more preferably 65% to 97% by mass, based on the total solid content of the composition, in terms of greater advantages of the present invention.

The resist composition may include only one type of resin (C) or two or more types of resin (C). When two or more types of resin (C) are included, the total amount thereof is preferably in the above range.

### [Ionic Compound]

The resist composition includes an ionic compound represented by the formula (III) (hereinafter also referred to as a “specific photoacid generator”).

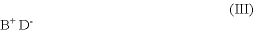

In the formula (III), B⁺ denotes a sulfonium cation or an iodonium cation. The cation denoted by B⁺ is decomposed by absorbing irradiated light, and the resulting radical cationic species extracts hydrogen.

The cation denoted by B⁺ is preferably a cation represented by the formula (ZaI) (cation (ZaI)) or a cation represented by the formula (ZaII) (cation (ZaII)).

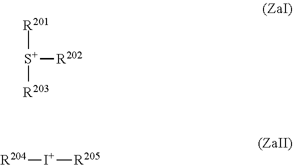

In the formula (ZaI), R²⁰¹ to R²⁰³ each independently denote an organic group.

The number of carbon atoms in each organic group denoted by R²⁰¹ to R²⁰³ preferably ranges from 1 to 30, more preferably 1 to 20. Two of the organic groups denoted by R²⁰¹ to R²⁰³ may be bonded together to form a ring structure, and the formed ring may include an oxygen atom, a sulfur atom, an ester group, an amide group, or a carbonyl group. In the ring structure, a group formed by bonding of two of the organic groups denoted by R²⁰¹ to R²⁰³ is, for example, an alkylene group (for example, a butylene group or a pentylene group) or —CH₂—CH₂—O—CH₂—CH₂—.

In the formula (ZaII), R²⁰⁴ and R²⁰⁵ each independently denote a monovalent aromatic group optionally having a substituent or an alkyl group optionally having a substituent, preferably a monovalent aromatic group in terms of greater advantages of the present invention.

The monovalent aromatic group denoted by R²⁰⁴ or R²⁰⁵ may be an aryl group or a heteroaryl group.

The aryl group is preferably a phenyl group or a naphthyl group, more preferably a phenyl group.

The heteroaryl group has a heteroatom, such as an oxygen atom, a nitrogen atom, or a sulfur atom. A ring constituting the heteroaryl group may be a pyrrole ring, a furan ring, a thiophene ring, an indole ring, a benzofuran ring, a benzothiophene ring, or the like.

The alkyl group denoted by R²⁰⁴ or R²⁰⁵ is preferably a linear alkyl group with 1 to 10 carbon atoms or a branched alkyl group with 3 to 10 carbon atoms (for example, a methyl group, an ethyl group, a propyl group, a butyl group, or a pentyl group) or a cyclic alkyl group with 3 to 10 carbon atoms (for example, a cyclopentyl group, a cyclohexyl group, or a norbornyl group).

The monovalent aromatic group and the alkyl group denoted by R²⁰⁴ or R²⁰⁵ may further have another substituent, for example, an alkyl group (for example, with 1 to 15 carbon atoms), a monovalent aromatic group (for example, with 6 to 15 carbon atoms), an alkoxy group (for example, with 1 to 15 carbon atoms), a halogen atom, a hydroxy group, a phenylthio group, or the like.

In particular, the cation (ZaI) is preferably a cation (ZaI-1), a cation (ZaI-2), or an organic cation represented by the formula (ZaI-3b) or the formula (ZaI-4b).

First, the cation (ZaI-1) is described below.

In the cation (ZaI-1), at least one of R²⁰¹ to R²⁰³ denotes a monovalent aromatic group optionally having a substituent. All of R²⁰¹ to R²⁰³ may be a monovalent aromatic group, or part of R²⁰¹ to R²⁰³ may be a monovalent aromatic group and the remainder may be an alkyl group optionally having a substituent.

One of R²⁰¹ to R²⁰³ may denote a monovalent aromatic group, and the remaining two of R²⁰¹ to R²⁰³ may be bonded together to form a ring structure. The formed ring may include an oxygen atom, a sulfur atom, an ester group, an amide group, or a carbonyl group. A group formed by bonding of two of R²⁰¹ to R²⁰³ is, for example, an alkylene group (for example, a butylene group, a pentylene group, or —CH₂—CH₂—O—CH₂—CH₂—) in which one or more methylene groups may be substituted with an oxygen atom, a sulfur atom, an ester group, an amide group, and/or a carbonyl group.

In the cation (ZaI-1), the monovalent aromatic group may be an aryl group or a heteroaryl group.

The aryl group is preferably a phenyl group or a naphthyl group, more preferably a phenyl group.

The heteroaryl group has a heteroatom, such as an oxygen atom, a nitrogen atom, or a sulfur atom. A ring constituting the heteroaryl group may be a pyrrole ring, a furan ring, a thiophene ring, an indole ring, a benzofuran ring, a benzothiophene ring, or the like.

In the cation (ZaI-1), when two or more of R²⁰¹ to R²⁰³ are monovalent aromatic groups, the two or more monovalent aromatic groups may be the same or different.

In the cation (ZaI-1), the alkyl group is preferably a linear alkyl group with 1 to 15 carbon atoms, a branched alkyl group with 3 to 15 carbon atoms, or a cyclic alkyl group with 3 to 15 carbon atoms, for example, a methyl group, an ethyl group, a propyl group, a n-butyl group, a sec-butyl group, a t-butyl group, a cyclopropyl group, a cyclobutyl group, a cyclohexyl group, or the like.

A substituent that the monovalent aromatic group and the alkyl group of R²⁰¹ to R²⁰³ may have may be each independently an alkyl group (for example, with 1 to 15 carbon atoms), a monovalent aromatic group (for example, with 6 to 14 carbon atoms), an alkoxy group (for example, with 1 to 15 carbon atoms), a cycloalkylalkoxy group (for example, with 1 to 15 carbon atoms), a halogen atom, a hydroxy group, or a phenylthio group.

The substituent may further have another substituent. For example, the alkyl group may have a halogen atom as a substituent to form a halogenated alkyl group, such as a trifluoromethyl group.

The cation (ZaI-1) is, for example, a triarylsulfonium cation, a diarylalkylsulfonium cation, an aryldialkylsulfonium cation, a diarylcycloalkylsulfonium cation, or an aryldicycloalkylsulfonium cation, and is preferably a triarylsulfonium cation in terms of greater advantages of the present invention.

Next, the cation (ZaI-2) is described.

In the cation (ZaI-2), R²⁰¹ to R²⁰³ each independently denote an organic group having no aromatic ring. The aromatic ring also includes a heterocycle including a heteroatom.

The organic group having no aromatic ring denoted by R²⁰¹ to R²⁰³ typically has 1 to 30 carbon atoms, preferably 1 to 20 carbon atoms.

R²⁰¹ to R²⁰³ preferably each independently denote an alkyl group, an allyl group, or a vinyl group, more preferably a linear or branched 2-oxoalkyl group, a 2-oxocycloalkyl group, or an alkoxycarbonylmethyl group, still more preferably a linear or branched 2-oxoalkyl group.

In the cation (ZaI-2), the alkyl group is, for example, a linear alkyl group with 1 to 10 carbon atoms (for example, a methyl group, an ethyl group, a propyl group, a butyl group, or a pentyl group), a branched alkyl group with 3 to 10 carbon atoms, or a cyclic alkyl group with 3 to 10 carbon atoms (for example, a cyclopentyl group, a cyclohexyl group, or a norbornyl group).

The alkyl group denoted by R²⁰¹ to R²⁰³ may be further substituted with a halogen atom, an alkoxy group (for example, with 1 to 5 carbon atoms), a hydroxy group, a cyano group, or a nitro group.

Next, the organic cation represented by the formula (ZaI-3b) is described.

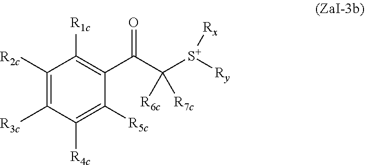

In the formula (ZaI-3b), R_{1c} to R_{5c} each independently denote a hydrogen atom, an alkyl group, a monovalent aromatic group, an alkoxy group, an aryloxy group, an alkoxycarbonyl group, an alkylcarbonyloxy group, a cycloalkylcarbonyloxy group, a halogen atom, a hydroxy group, a nitro group, an alkylthio group, or an arylthio group.

R_{6c} and R_{7c} each independently denote a hydrogen atom, an alkyl group (such as a t-butyl group), a halogen atom, a cyano group, or an aryl group.

Rₓ and R_{y} each independently denote an alkyl group, a linear or branched 2-oxoalkyl group, a 2-oxocycloalkyl group, an alkoxycarbonylalkyl group, an allyl group, or a vinyl group.

Two or more of R_{1c} to R_{5c}, R_{5c} and R_{6c}, R_{6c} and R_{7c}, R_{5c} and Rₓ, or Rₓ and R_{y} may be bonded together to form a ring, and the formed ring may each independently include an oxygen atom, a sulfur atom, a ketone group, an ester group, or an amide bond.

The ring may be an aromatic or non-aromatic hydrocarbon ring, an aromatic or non-aromatic heterocycle, or a polycyclic fused ring formed by combining two or more of these rings. The ring may be a 3- to 10-membered ring, preferably a 4- to 8-membered ring, more preferably a 5- or 6-membered ring.

A group formed by combining two or more of R_{1c} to R_{5c}, R_{6c} and R_{7c}, or Rₓ and R_{y} may be an alkylene group, such as a butylene group or a pentylene group. A methylene group in the alkylene group may be substituted with a heteroatom, such as an oxygen atom.

A group formed by combining R_{5c} and R_{6c}, or R_{5c} and Rₓ is preferably a single bond or an alkylene group. The alkylene group may be a methylene group, an ethylene group, or the like.

Next, the organic cation represented by the formula (ZaI-4b) is described.

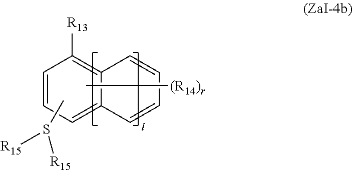

In the formula (ZaI-4b), 1 denotes an integer in the range of 0 to 2, and r denotes an integer in the range of 0 to 8.

R₁₃ denotes a hydrogen atom, a fluorine atom, a hydroxy group, a linear or branched alkyl group, an alkoxy group, an alkoxycarbonyl group, or a group having a cycloalkyl group (which may be the cycloalkyl group itself or a group partially including the cycloalkyl group). These groups may have a substituent.

R₁₄ denotes a hydroxy group, a linear or branched alkyl group, an alkoxy group, an alkoxycarbonyl group, an alkylcarbonyl group, an alkylsulfonyl group, a cycloalkylsulfonyl group, or a group having a cycloalkyl group (which may be the cycloalkyl group itself or a group partially including the cycloalkyl group). These groups may have a substituent. A plurality of R₁₄s, if present, each independently denote the group described above, such as a hydroxy group.

R₁₅ each independently denotes an alkyl group or a naphthyl group. These groups may have a substituent. Two R₁₅s may be bonded together to form a ring. When two R₁₅s are bonded together to form a ring, the ring skeleton may include a heteroatom, such as an oxygen atom or a nitrogen atom. In one embodiment, preferably, two R₁₅s are alkylene groups and are bonded together to form a ring structure.

In the formula (ZaI-4b), the alkyl group denoted by R₁₅ may be linear, branched, or cyclic. The number of carbon atoms in the alkyl group preferably ranges from 1 to 10. The alkyl group is preferably a methyl group, an ethyl group, a n-butyl group, or a t-butyl group.

Preferred forms of the cation denoted by B⁺ are shown below, but the present invention is not limited thereto.

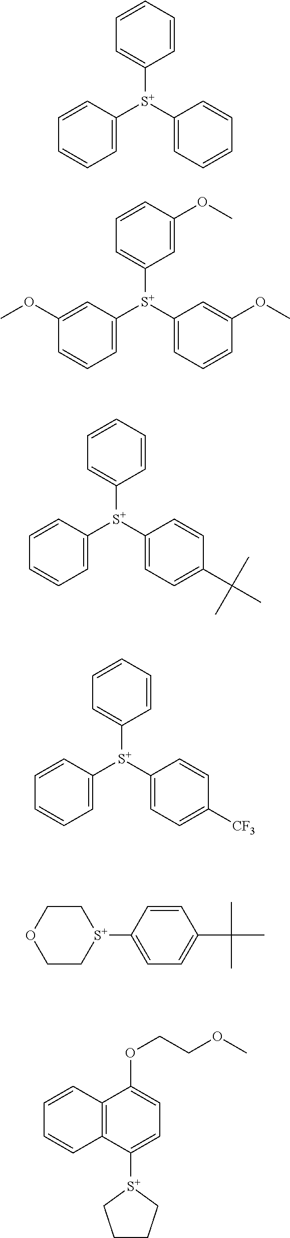

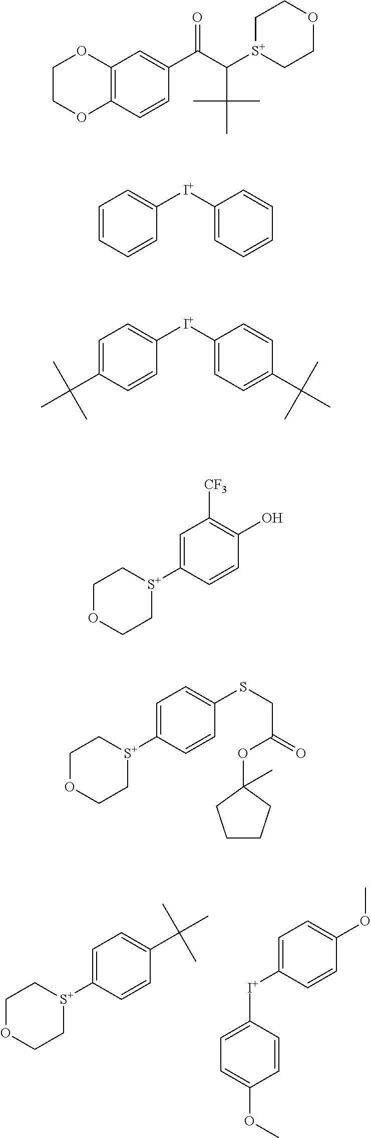

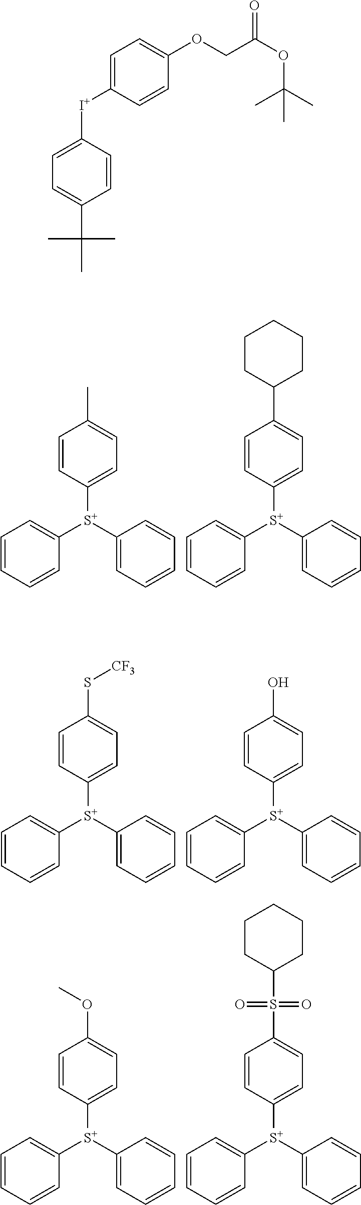

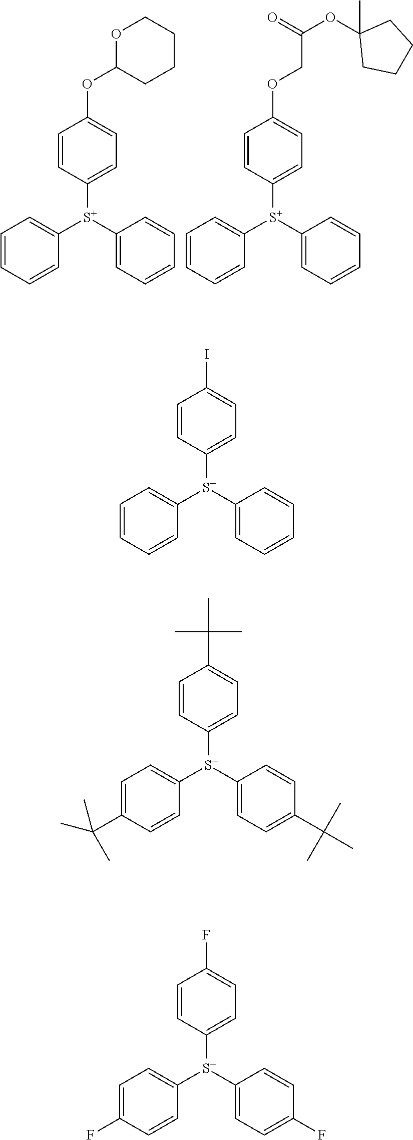 [SMILES: c1ccc([S+](c2ccccc2)c2ccc(OC3CCCCO3)cc2)cc1 ; CC1(OC(=O)COc2ccc([S+](c3ccccc3)c3ccccc3)cc2)CCCC1 ; Ic1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; Fc1ccc([S+](c2ccc(F)cc2)c2ccc(F)cc2)cc1]

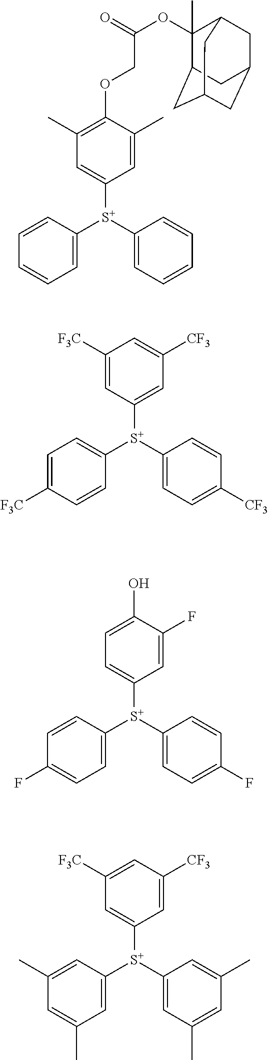

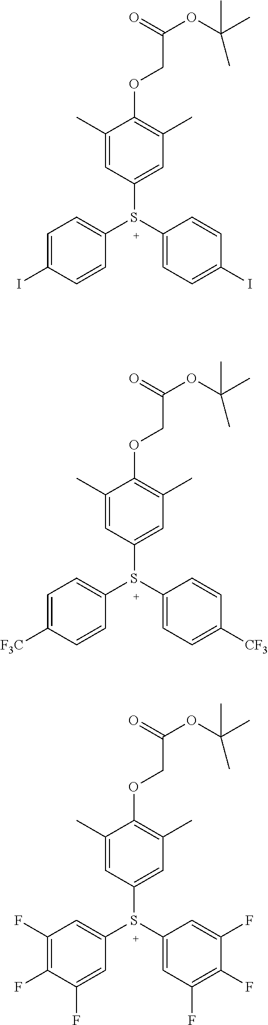

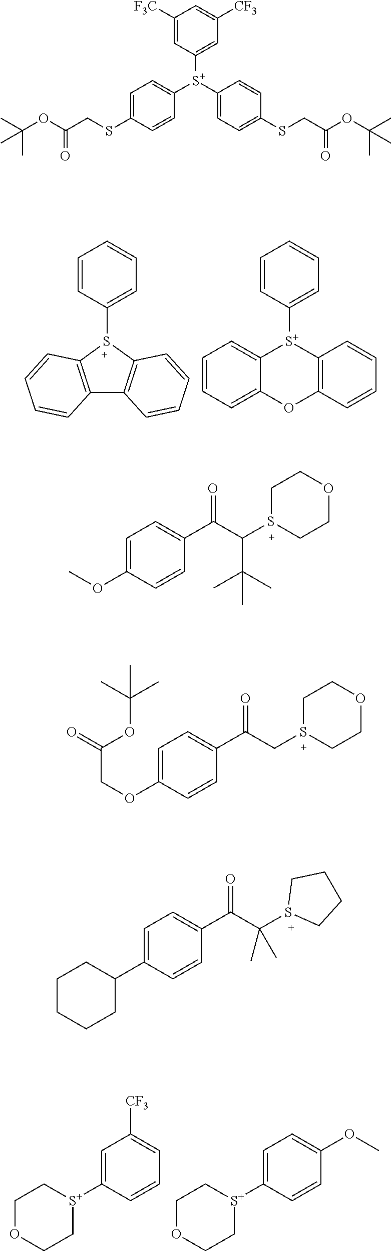

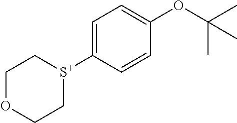 [SMILES: CC(C)(C)Oc1ccc([S+]2CCOCC2)cc1]

Furthermore, for B⁺, the contents described in paragraphs to [0177] to [0188], [0193], and of JP2013-127526A can also be referred to and are incorporated into the present specification.

In the formula (III), D⁻ denotes a hydroxide ion, an anion formed by dissociation of a proton (H⁺) from a hydroxy group in a compound having the hydroxy group, or an anion formed by dissociation of a proton from a carboxy group in a compound having the carboxy group.

The anion denoted by D⁻ is preferably a hydroxide ion or an organic anion represented by the formula (ZbI).

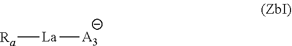

In the formula (ZbI),
Rₐ denotes a hydrogen atom or a monovalent organic group.
Lₐ denotes a single bond or a divalent linking group.
A₃⁻ denotes —O⁻ or —COO⁻.

The monovalent organic group denoted by Rₐ is not particularly limited, and the number of carbon atoms in the monovalent organic group preferably ranges from 1 to 30, more preferably 1 to 20.

The monovalent organic group is, for example, an alkyl group, a monovalent aromatic group, an aralkyl group, or the like. Among these, the monovalent organic group denoted by Rₐ is preferably an alkyl group or an aryl group. The alkyl group and the aryl group may further have a substituent. A substituent that the alkyl group and the aryl group may have may be, but is not limited to, any of the groups presented as examples of the substituent T, for example, a hydroxy group, a halogen atom, or an alkyl group optionally substituted with a halogen atom.

The alkyl group may be linear, branched, or cyclic.

The number of carbon atoms in the linear or branched alkyl group preferably ranges from 1 to 20, more preferably 1 to 15, still more preferably 1 to 10.

When the alkyl group is cyclic, the cyclic alkyl group (cycloalkyl group) may be monocyclic or polycyclic. The number of carbon atoms in the cyclic alkyl group preferably ranges from 3 to 20, more preferably 3 to 15, still more preferably 3 to 10.

The aryl group may be monocyclic or polycyclic.

The number of carbon atoms in the aryl group preferably ranges from 6 to 20, more preferably 6 to 15, still more preferably 6 to 10.

The cycloalkyl group may include a heteroatom as a ring atom. The heteroatom may be, but is not limited to, a nitrogen atom, an oxygen atom, or the like.

The cycloalkyl group may include a carbonyl bond (>C═O) as a ring atom.

The divalent linking group denoted by Lₐ is, for example, but not limited to, an alkylene group, a divalent aromatic group, —O—, —CO—, —COO—, or a group formed by combining two or more thereof.

The alkylene group may be linear, branched, or cyclic.

The number of carbon atoms in the linear or branched alkylene group preferably ranges from 1 to 20, more preferably 1 to 10.

When the alkylene group is cyclic, the cyclic alkylene group (cycloalkylene group) may be monocyclic or polycyclic. The number of carbon atoms in the cyclic alkylene group preferably ranges from 3 to 20, more preferably 3 to 10.

The number of carbon atoms in the divalent aromatic group preferably ranges from 6 to 20, more preferably 6 to 15.

An aromatic ring constituting the divalent aromatic group may be, but is not limited to, an aromatic hydrocarbon or a heteroaromatic ring. The aromatic ring is, for example, a benzene ring, a naphthalene ring, an anthracene ring, or a thiophene ring and is preferably a benzene ring or a naphthalene ring, more preferably a benzene ring.

The alkylene group and the divalent aromatic group may further have a substituent.

A substituent that the alkylene group and the divalent aromatic group may have is, but not limited to, any of the groups presented as examples of the substituent T, preferably a halogen atom.

A₃⁻ denotes —O⁻ or —COO⁻. —O⁻ is a group formed by dissociation of a proton from a hydroxy group. —COO⁻ is a group formed by dissociation of a proton from a carboxy group.

Preferred forms of the anion denoted by D⁻ are shown below, but the present invention is not limited thereto.

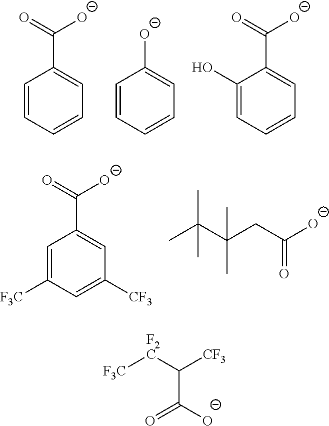 [SMILES: O=C([O-])c1ccccc1 ; [O-]c1ccccc1 ; O=C([O-])c1ccccc1O ; O=C([O-])c1cc(C(F)(F)F)cc(C(F)(F)F)c1 ; CC(C)(C)C(C)(C)CC(=O)[O-] ; O=C([O-])C(C(F)(F)F)C(F)(F)C(F)(F)F]

Furthermore, for the anion denoted by D⁻, for example, the contents described in paragraphs [0215] to [0216], [0220], and [0229] to [0230] of JP2013-127526A can also be referred to and are incorporated into the present specification.

When D⁻ is an anion formed by dissociation of a proton from a carboxy group in a specific compound having the carboxy group and not including an aromatic ring, the specific compound has a C log P value of 3.00 or less.

The lower limit of the C log P value of the specific compound is preferably, but not limited to, −2.00 or more.

The specific compound is, for example, a compound represented by the formula (V) and having a C log P value of 3.00 or less.

R—COOH Formula (V)

R denotes an alkyl group optionally having a substituent.

The number of carbon atoms in the alkyl group preferably ranges from 1 to 20, more preferably 3 to 10.

The substituent may be any of the groups presented as examples of the substituent T described above and is preferably a halogen atom.

When D⁻ is an anion other than an anion formed by dissociation of a proton from a carboxy group in the specific compound, the C log P value of a compound (D⁻H⁺) formed by bonding of a proton to the anion is preferably, but not limited to, 5.00 or less, more preferably 4.00 or less, still more preferably 3.00 or less, in terms of greater advantages of the present invention. The lower limit is, for example, but not limited to, −2.00 or more.

The specific photoacid generator content of the resist composition is, but not limited to, often 0.01 to 1.50 mmol/g, preferably 0.10 to 1.00 mmol/g, based on the total solid content of the resist composition in terms of greater advantages of the present invention.

The resist composition may include only one type of specific photoacid generator or two or more types of specific photoacid generator. When two or more types of specific photoacid generator are included, the total amount thereof is preferably in the above range.

### [Other Optional Components]

### <Solvent>

The resist composition may include a solvent.

The solvent preferably includes at least one of (M1) a propylene glycol monoalkyl ether carboxylate (such as propylene glycol monomethyl ether acetate (PGMEA)) or (M2) at least one selected from the group consisting of a propylene glycol monoalkyl ether (such as propylene glycol monomethyl ether (PGME) or propylene glycol monoethyl ether (PGEE)), a lactate (such as ethyl lactate), an acetate, an alkoxy propionic acid ester, a chain ketone, a cyclic ketone (such as 2-heptanone, cyclohexanone, or cyclopentanone), lactone (such as γ-butyrolactone), and an alkylene carbonate (such as propylene carbonate). The solvent may further include a component other than the components (M1) and (M2).

The solvent preferably includes the component (M1). More preferably, the solvent consists essentially of the component (M1) alone or is a mixed solvent of the component (M1) and another component. In the latter case, the solvent still more preferably includes both the component (M1) and the component (M2).

The mass ratio (M1/M2) of the component (M1) to the component (M2) preferably ranges from “100/0” to “0/100”, more preferably “100/0” to “15/85”, still more preferably “100/0” to “40/60”, particularly preferably “100/0” to “60/40”.

As described above, the solvent may further include a component other than the components (M1) and (M2). In this case, the amount of the components other than the components (M1) and (M2) preferably ranges from 5% to 30% by mass based on the total amount of the solvent.

The solvent content of the resist composition is determined so that the concentration of solid contents preferably ranges from 0.5% to 30% by mass, more preferably 1% to 20% by mass.

### <Surfactant>

The resist composition may further include a surfactant.

The surfactant is preferably a fluorinated and/or silicon surfactant.

The fluorinated and/or silicon surfactant may be a surfactant disclosed in paragraphs [0218] and [0219] of WO2018/193954A.

When the resist composition includes a surfactant, the surfactant content preferably ranges from 0.0001% to 2% by mass, more preferably 0.0005% to 1% by mass, based on the total solid content of the composition.

The resist composition may include only one type of surfactant or two or more types of surfactant. When two or more types of surfactant are included, the total amount thereof is preferably in the above range.

The resist composition may further include a dissolution inhibiting compound, a dye, a plasticizer, a photosensitizer, a light absorber, and/or a compound that enhances solubility in a developer.

### {Requirement 3}

In terms of greater advantages of the present invention, the resist composition preferably satisfies the following requirement 3:
Requirement 3: when a polydispersity of the resin in a resist film formed using the actinic ray-sensitive or radiation-sensitive resin composition is denoted by PDI₀,
when the resist film is subjected to exposure treatment under an irradiation condition under which a weight-average molecular weight of a product produced by cleavage of the resin in the resist film is half the weight-average molecular weight of the resin, and the polydispersity of the product produced by cleavage of the resin is denoted by PDI₂,
when the resist film is subjected to exposure treatment under an irradiation condition under which the weight-average molecular weight of the product produced by cleavage of the resin in the resist film is one-third the weight-average molecular weight of the resin, and the polydispersity of the product produced by cleavage of the resin is denoted by PDI₃,
when the resist film is subjected to exposure treatment under an irradiation condition under which the weight-average molecular weight of the product produced by cleavage of the resin in the resist film is one-fourth the weight-average molecular weight of the resin, and the polydispersity of the product produced by cleavage of the resin is denoted by PDI₄,
when the resist film is subjected to exposure treatment under an irradiation condition under which the weight-average molecular weight of the product produced by cleavage of the resin in the resist film is one-fifth the weight-average molecular weight of the resin, and the polydispersity of the product produced by cleavage of the resin is denoted by PDI₅, and
when a highest value among PDI₂ to PDI₅ is denoted by PDIₘₐₓ, the relationship of the formula (1) is satisfied:

PDIₘₐₓ<1.3×PDI₀ Formula (1)

The polydispersities represented by PDI₀ and PDI₂ to PDI₅ can be measured with the GPC apparatus described above.

In a specific procedure of the requirement 3, first, a predetermined resist composition is applied to a silicon wafer to form a resist film. The resist film preferably has a thickness in the range of 15 to 100 nm.

When the resist film is formed, if necessary, drying treatment may be performed after the resist composition is applied. The conditions for the drying treatment may be the conditions described later in a step 1.

Next, the resist film is irradiated with a predetermined exposure amount of light. The light for photoirradiation is light that can cleave a main chain of the resin (C), preferably EUV light.

The resist film after the exposure is immersed in a predetermined solvent (for example, N-methylpyrrolidone) to dissolve the resist film, and the resulting solution sample is used to measure the weight-average molecular weight of a product produced by cleavage of the resin (C).

Using the above procedure, the irradiation conditions (exposure amount) under which the weight-average molecular weight of a product produced by cleavage of the resin (C) is half, one-third, one-fourth, or one-fifth the weight-average molecular weight of the resin (C) before photoirradiation are found to determine the polydispersities PDI₂ to PDI₅ of the product produced by cleavage of the resin (C) under the respective irradiation conditions.

The highest value among the polydispersities PDI₂ to PDI₅ is selected as PDIₘₐₓ, and PDIₘₐₓ is compared with the polydispersity PDI₀ of the resin (C) before photoirradiation to examine whether the relationship of the formula (1) is satisfied.

When the resist composition satisfies the requirement 3, it means that a crosslinking reaction is less likely to proceed during the cleavage of the resin (C), the decrease in dissolution contrast is consequently small, and the DOF performance is further improved.

To satisfy the requirement 3, for example, there is a method of reducing the amount of repeating unit having only one phenolic hydroxy group in the resin (C) in the resist composition.

### {Requirement 41}

In terms of greater advantages of the present invention, the resist composition preferably satisfies the following requirement 4:
Requirement 4: when the dissolution rate in butyl acetate of a resist film formed by applying an actinic ray-sensitive or radiation-sensitive resin composition to a silicon wafer and heating the actinic ray-sensitive or radiation-sensitive resin composition at 80° C. for 60 seconds is denoted by DR₁, and when the dissolution rate in butyl acetate of a resist film formed by applying the actinic ray-sensitive or radiation-sensitive resin composition to a silicon wafer and heating the actinic ray-sensitive or radiation-sensitive resin composition at 130° C. for 60 seconds is denoted by DR₂, the relationship of the formula (2) is satisfied:

DR₁>1.1×DR₂ Formula (2)

In a specific procedure of the requirement 4, first, a predetermined resist composition is applied to a silicon wafer, and the coating film is heated at 80° C. for 60 seconds to form a resist film. The resist film preferably has a thickness in the range of 15 to 100 nm.

Next, the formed resist film is brought into contact with butyl acetate to calculate the dissolution rate DR₁ of the resist film. The resist film may be brought into contact with butyl acetate by a method of immersing a silicon wafer with the resist film in butyl acetate. The immersion time preferably ranges from 100 to 2000 seconds. The resist film after the immersion is dried with a spin coater (rotational speed: 400 rpm, rotation time: 30 seconds) to measure the thickness FT₁ of the resist film.

Next, the dissolution rate DR₁ is calculated using the following formula from the thickness of the resist film before contact with butyl acetate (initial thickness), the thickness FT₁, and the immersion time:

Dissolution rate DR₁=(initial thickness−FT₁)/(immersion time)(nm/s)

The dissolution rate DR₂ is calculated in the same manner as described above except that the condition of the heat treatment is changed from 80° C. for 60 seconds to 130° C. for 60 seconds.

Whether or not the calculated dissolution rates DR₁ and DR₂ satisfy the relationship of the formula (2) is examined.

When the resist composition satisfies the requirement 4, it can be said that the resist film heated at a higher temperature has a lower dissolution rate in an organic solvent, and heating further strengthens the interaction between the resin (C) and an ionic compound in the resist film. The strong interaction means that, due to a high dissolution contrast between an unexposed portion and an exposed portion at the time of exposure, the resist film has higher DOF performance.

To satisfy the requirement 4, for example, there is a method of relatively increasing the ionic compound content of the resist composition and thereby strengthening the interaction between the resin (C) and the ionic compound.

### [Resist Film and Pattern Forming Method]

The procedure of a pattern forming method using the resist composition is not particularly limited and preferably includes the following steps:
Step 1: A step of forming a resist film on a substrate using the resist composition
Step 2: A step of exposing the resist film
Step 3: A step of developing the exposed resist film using a developer including an organic solvent to form a pattern

The procedure of each step is described in detail below.

### <Step 1: Resist Film Forming Step>

The step 1 is a step of forming a resist film on a substrate using the resist composition.

The resist composition is defined as described above.

A method of forming a resist film on a substrate using the resist composition is, for example, a method of applying the resist composition to a substrate.

If necessary, the resist composition is preferably filtered before application. The filter preferably has a pore size of 0.1 μm or less, more preferably 0.05 μm or less, still more preferably 0.03 μm or less. The filter is preferably made of polytetrafluoroethylene, polyethylene, or nylon.

The resist composition can be applied to a substrate (for example, silicon covered with silicon dioxide), which may be used in the production of an integrated circuit element, by an appropriate application method using a spinner, a coater, or the like. The application method is preferably spin coating using a spinner. The rotational speed in spin coating using a spinner preferably ranges from 1000 to 3000 rpm.

After the application of the resist composition, the substrate may be dried to form a resist film. If necessary, an underlying film (an inorganic film, an organic film, or an antireflection film) may be formed under the resist film.

A material constituting a substrate to be processed and the outermost surface layer thereof is, for example, a silicon wafer in the case of a semiconductor wafer, and a material of the outermost surface layer is, for example, Si, SiO₂, SiN, SiON, TiN, WSi, BPSG (Boro-Phospho. Silicate Glass), SOG (Spin On Glass), an organic antireflection film, or the like.

The drying method is, for example, a method of drying by heating. The heating can be performed using a means provided in a typical exposure apparatus and/or developing apparatus or using a hot plate or the like. The heating temperature preferably ranges from 80° C. to 150° C., more preferably 80° C. to 140° C., still more preferably 80° C. to 130° C. The heating time preferably ranges from 30 to 1000 seconds, more preferably 60 to 800 seconds, still more preferably 60 to 600 seconds. The resist film can be formed, for example, by prebaking at 60° C. to 150° C. for 1 to 20 minutes, preferably at 80° C. to 120° C. for 1 to 10 minutes.

The thickness of the resist film is preferably, but not limited to, in the range of 10 to 120 nm from the perspective of forming a micropattern with higher accuracy. In particular, for EUV exposure, the resist film more preferably has a thickness in the range of 10 to 65 nm, still more preferably 15 to 50 nm.

A top coat may be formed on the resist film using a top coat composition.

Preferably, the top coat composition is not mixed with the resist film and can be homogeneously applied to an upper layer of the resist film.

The top coat preferably has a thickness in the range of 10 to 200 nm, more preferably 20 to 100 nm, still more preferably 40 to 80 nm.

The top coat may be, but is not limited to, a known top coat formed by a known method, for example, a top coat formed on the basis of the description in paragraphs [0072] to [0082] of JP2014-059543A.

For example, a top coat including a basic compound as described in JP2013-061648A is preferably formed on the resist film. A specific example of a basic compound that can be included in a top coat may be a basic compound that may be included in the resist composition.

The top coat also preferably includes a compound including at least one group or bond selected from the group consisting of an ether bond, a thioether bond, a hydroxy group, a thiol group, a carbonyl group, and an ester group.

### <Step 2: Exposure Step>

The step 2 is a step of exposing the resist film.

The exposure method may be a method of irradiating a formed resist film with an actinic ray or radiation through a predetermined mask.

The actinic ray or radiation may be infrared light, visible light, ultraviolet light, far-ultraviolet light, extreme ultraviolet light, X-rays, or an electron beam, preferably far-ultraviolet light with a wavelength of 250 nm or less, more preferably 220 nm or less, particularly preferably 1 to 200 nm, more specifically, a KrF excimer laser (248 nm), an ArF excimer laser (193 nm), an F₂ excimer laser (157 nm), EUV (13 nm), X-rays, or an electron beam.

The exposure is preferably followed by post-exposure heat treatment (also referred to as post-exposure baking) before development. The post-exposure heat treatment promotes a reaction in the exposed portion and improves sensitivity and the pattern shape.

The heating temperature preferably ranges from 80° C. to 150° C., more preferably 80° C. to 140° C., still more preferably 80° C. to 130° C.

The heating time preferably ranges from 10 to 1000 seconds, more preferably 10 to 180 seconds, still more preferably 30 to 120 seconds.

The heating can be performed using a means provided in a typical exposure apparatus and/or developing apparatus or using a hot plate or the like. This step is also referred to as post-exposure baking.

### <Step 3: Developing Step>

The step 3 is a step of developing the exposed resist film using a developer including an organic solvent to form a pattern.

The developing method is, for example, a method of dipping a substrate in a vessel filled with the developer for a certain period (a dip method), a method of raising the developer on the surface of a substrate by surface tension and standing still for a certain period for development (a paddle method), a method of spraying the developer on the surface of a substrate (a spray method), or a method of continuously ejecting the developer while moving a developer ejection nozzle at a constant speed on a substrate rotating at a constant speed (a dynamic dispense method).

The developing step may be followed by a step of stopping the development during substitution with another solvent.

The development time is preferably, but not limited to, 10 to 300 seconds, more preferably 20 to 120 seconds, provided that the resin in an unexposed portion is sufficiently dissolved.

The temperature of the developer preferably ranges from 0° C. to 50° C., more preferably 15° C. to 35° C.

An organic solvent in the developer is preferably at least one selected from the group consisting of a ketone solvent, an ester solvent, an alcohol solvent, an amide solvent, an ether solvent, and a hydrocarbon solvent.

The C log P value of an organic solvent in the developer is preferably, but not limited to, 0.00 or more, more preferably 1.00 or more. When two or more organic solvents are included, the C log P value of a mixed solvent thereof is preferably in the above range.

The ketone solvent is, for example, 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, or the like.

The ester solvent is, for example, methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butyrate, methyl 2-hydroxyisobutyrate, isoamyl acetate, isobutyl isobutyrate, butyl propionate, or the like.

The alcohol solvent, the amide solvent, the ether solvent, and the hydrocarbon solvent are, for example, the solvents disclosed in paragraphs [0715] to [0718] of US2016/0070167A.

A plurality of these solvents may be mixed together, or these solvents may be mixed with water or a solvent other than these solvents. The moisture content of the developer as a whole is preferably less than 50% by mass, more preferably less than 20% by mass, still more preferably less than 10% by mass, and it is particularly preferable that the developer include substantially no moisture.

The organic solvent content of the developer preferably ranges from 50% to 100% by mass, more preferably 80% to 100% by mass, still more preferably 90% to 100% by mass, particularly preferably 95% to 100% by mass, based on the total amount of the developer.

In terms of greater advantages of the present invention, the developer preferably includes a first organic solvent and a second organic solvent, and the first organic solvent more preferably has a higher boiling point than the second organic solvent and has a higher C log P value than the second organic solvent. The boiling point means a boiling point at 1 atm (760 mmHg).

The ratio of the first organic solvent content to the second organic solvent content of the developer is not particularly limited. In terms of greater advantages of the present invention, the mass ratio of the second organic solvent content to the first organic solvent content preferably ranges from 1 to 50, more preferably 3 to 20.

In terms of greater advantages of the present invention, the second organic solvent in the developer is preferably the ketone solvent or the ester solvent, more preferably the ester solvent, still more preferably butyl acetate or isoamyl butyrate. The first organic solvent is preferably, but not limited to, an organic solvent with a C log P value of 3.00 or more, more preferably a hydrocarbon solvent.

### <Step 4: Rinsing Step>

The pattern forming method preferably includes a step 4 of washing the pattern using a rinse liquid including an organic solvent after the step 3.

The rinse liquid includes an organic solvent.

The organic solvent in the rinse liquid is preferably at least one organic solvent selected from the group consisting of a hydrocarbon solvent, a ketone solvent, an ester solvent, an alcohol solvent, an amide solvent, and an ether solvent.

Examples of the hydrocarbon solvent, the ketone solvent, the ester solvent, the alcohol solvent, the amide solvent, and the ether solvent include those similar to the solvents described above for the developer including the organic solvent.

In terms of greater advantages of the present invention, the rinse liquid preferably includes a first organic solvent and a second organic solvent, and the first organic solvent more preferably has a higher boiling point than the second organic solvent and has a higher C log P value than the second organic solvent. The boiling point means a boiling point at 1 atm (760 mmHg).

The ratio of the first organic solvent content to the second organic solvent content of the rinse liquid is not particularly limited. In terms of greater advantages of the present invention, the mass ratio of the second organic solvent content to the first organic solvent content preferably ranges from 1 to 50, more preferably 3 to 20.

In terms of greater advantages of the present invention, the second organic solvent in the rinse liquid is preferably the ketone solvent or the ester solvent, more preferably the ester solvent, still more preferably butyl acetate or isoamyl butyrate. The first organic solvent is preferably, but not limited to, an organic solvent with a C log P value of 3.00 or more, more preferably a hydrocarbon solvent.

A method in the rinsing step is, for example, but not limited to, a method of continuously ejecting the rinse liquid to a substrate rotating at a constant speed (a spin coating method), a method of dipping a substrate in a vessel filled with the rinse liquid for a certain period (a dipping method), a method of spraying the rinse liquid on the surface of a substrate (a spray method), or the like.

The pattern forming method according to the present invention may include a heating step (post bake) after the rinsing step. In this step, the developer and the rinse liquid remaining between patterns and inside patterns are removed by baking. This step also has an effect of annealing a resist pattern and improving the surface roughness of the pattern. The heating step after the rinsing step is preferably performed at 40° C. to 250° C. (preferably 90° C. to 200° C.) for 10 seconds to 3 minutes (preferably 30 seconds to 120 seconds).

A formed pattern may be used as a mask to perform etching on a substrate to be etched. More specifically, the pattern formed in the step 3 may be used as an etching mask to process a substrate (or an underlayer film and the substrate) and form a pattern on the substrate.

The substrate (or the underlayer film and the substrate) may be processed by any method, preferably by a method of using the pattern formed in the step 3 as a mask to dry-etching the substrate (or the underlayer film and the substrate) and form a pattern on the substrate. The dry etching is preferably oxygen plasma etching.

In terms of greater advantages of the present invention, preferably, the developer includes two or more organic solvents when the pattern forming method does not include the step 4, and at least one of the developer or the rinse liquid includes two or more organic solvents when the pattern forming method includes the step 4.

The two or more organic solvents in the developer and the rinse liquid are preferably a combination of the first organic solvent and the second organic solvent described above.

Various materials used in the resist composition and in the pattern forming method according to the present invention (for example, a solvent, a developer, a rinse liquid, a composition for forming an antireflection film, a composition for forming a top coat, and the like) preferably do not include impurities, such as metals. The impurity content of each material is preferably 1 ppm by mass or less, more preferably 10 ppb by mass or less, still more preferably 100 ppt by mass or less, particularly preferably 10 ppt by mass or less, most preferably 1 ppt by mass or less. The metal impurities are, for example, Na, K, Ca, Fe, Cu, Mg, Al, Li, Cr, Ni, Sn, Ag, As, Au, Ba, Cd, Co, Pb, Ti, V, W, Zn, and/or the like.

A method for removing impurities, such as metals, from the various materials is, for example, filtration using a filter. Details of filtration using a filter are described in paragraph [0321] of WO2020/004306A.

A method of reducing impurities, such as metals, in the various materials is, for example, a method of selecting a raw material with a low metal content as a raw material constituting the various materials, a method of filtering a raw material constituting the various materials through a filter, a method of performing distillation under conditions in which contamination is suppressed as much as possible by lining the inside of an apparatus with Teflon (registered trademark), or the like.

In addition to filter filtration, impurities may be removed using an adsorbent, or filter filtration and an adsorbent may be used in combination. The adsorbent may be a known adsorbent, for example, an inorganic adsorbent, such as silica gel or zeolite, or an organic adsorbent, such as activated carbon. To reduce impurities, such as metals, in the various materials, it is necessary to prevent contamination with metal impurities in the production process. Whether or not metal impurities are sufficiently removed from a production apparatus can be confirmed by measuring the metal component content of a washing liquid used for washing the production apparatus. The metal component content of the used washing liquid preferably ranges from 100 parts per trillion (ppt) by mass or less, more preferably 10 ppt by mass or less, still more preferably 1 ppt by mass or less.

A method for improving the surface roughness of a pattern may be applied to a pattern formed by a method according to the present invention. The method for improving the surface roughness of a pattern is, for example, a method for treating a pattern with plasma of a gas including hydrogen disclosed in WO2014/002808A. Another method may be a known method described in JP2004-235468A, US2010/0020297A, JP2008-83384A, or Proc. of SPIE Vol. 8328 83280N-1 “EUV Resist Curing Technique for LWR Reduction and Etch Selectivity Enhancement”.

### [Method for Producing Electronic Device]

The present invention also relates to a method for producing an electronic device including the pattern forming method and to an electronic device produced by the production method.

An electronic device according to the present invention is suitably mounted on electrical and electronic equipment (home appliances, office automation (OA), media-related equipment, optical equipment, communication equipment, and the like).

### EXAMPLES

The present invention is described in more detail in the following examples. The materials, amounts used, ratios, details of treatment, treatment procedures, and the like in the following examples can be appropriately changed without departing from the gist of the present invention. Thus, the scope of the present invention should not be construed as being limited to the examples described below.

### [Various Components of Actinic Ray-Sensitive or Radiation-Sensitive Resin Composition]

Various components used for the preparation of actinic ray-sensitive or radiation-sensitive resin compositions and materials used for evaluation are described below.

### [Resin (C)]

The structures of repeating units derived from monomers used for the synthesis of the resins P-1 to P-13 shown in Table 3 are shown below.

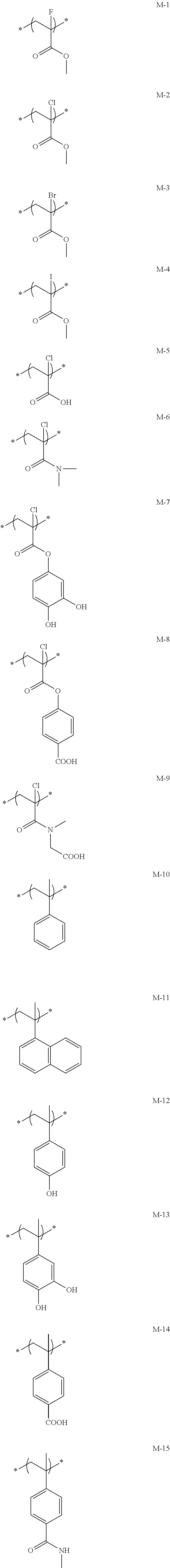

The resins P-2 to P-13 were synthesized in accordance with a method for synthesizing the resin P-1 described later (Synthesis Example 1) or a known method. Table 1 shows the compositional ratio, the weight-average molecular weight (Mw₀), the number-average molecular weight (Mn₀), and the polydispersity (Mw₀/Mn₀ (PDI₀)) of each repeating unit of the resins.

The weight-average molecular weight (Mw₀), the number-average molecular weight (Mn₀), and the polydispersity (PDI₀) of each of the resins P-1 to P-13 were measured as polystyrene equivalents by gel permeation chromatography (GPC) using a GPC apparatus (HLC-8120GPC manufactured by Tosoh Corporation) (solvent: tetrahydrofuran, flow rate (sample injection volume): 10 μL, column: TSK gel Multipore HXL-M manufactured by Tosoh Corporation, column temperature: 40° C., flow rate: 1.0 mL/min, detector: differential refractive index detector). The compositional ratios (mol % ratios) of the resins P-1 to P-13 were measured by ¹³C-NMR (Nuclear Magnetic Resonance).

TABLE 1

| Resin (C) | Contained repeating unit (mol %) | | | | Mw₀ | Mn₀ | PDI₀ |
|---|---|---|---|---|---|---|---|
| P-1 | M-2 | M-13 | M-10 | — | 18,000 | 8,500 | 2.1 |
| | 50 | 25 | 25 | — | | | |
| P-2 | M-4 | M-13 | M-10 | — | 18,000 | 8,500 | 2.1 |
| | 50 | 5 | 45 | — | | | |
| P-3 | M-2 | M-13 | M-10 | | 24,000 | 11,500 | 2.1 |
| | 50 | 25 | 25 | — | | | |
| P-4 | M-3 | M-13 | M-11 | — | 35,000 | 17,000 | 2.1 |
| | 40 | 40 | 20 | — | | | |
| P-5 | M-2 | M-5 | M-13 | M-10 | 35,000 | 19,000 | 1.8 |
| | 48 | 2 | 3 | 47 | | | |
| P-6 | M-6 | M-14 | M-10 | — | 35,000 | 22,000 | 1.6 |
| | 50 | 30 | 20 | — | | | |
| P-7 | M-1 | M-7 | M-14 | M-15 | 18,000 | 8,500 | 2.1 |
| | 30 | 20 | 20 | 30 | | | |
| P-8 | M-4 | M-8 | M-13 | M-10 | 18,000 | 8,500 | 2.1 |
| | 30 | 30 | 20 | 20 | | | |
| P-9 | M-2 | M-5 | M-13 | M-12 | 35,000 | 22,000 | 1.6 |
| | 40 | 10 | 40 | 10 | | | |
| P-10 | M-2 | M-9 | M-13 | M-10 | 35,000 | 22,000 | 1.6 |
| | 40 | 10 | 30 | 20 | | | |
| P-11 | M-2 | M-13 | M-12 | — | 18,000 | 8,500 | 2.1 |
| | 50 | 25 | 25 | — | | | |
| P-12 | M-2 | M-10 | M-15 | — | 18,000 | 8,500 | 2.1 |
| | 40 | 50 | 10 | — | | | |
| P-13 | M-2 | M-5 | M-13 | M-10 | 18,000 | 8,500 | 2.1 |
| | 30 | 20 | 25 | 25 | | | |

### Synthesis Example 1: Synthesis of Resin P-1

In a nitrogen stream, 194.3 g of cyclohexanone was placed in a three-neck flask and was heated to 80° C. 47.3 g, 49.5 g, and 23.2 g of monomers corresponding to the repeating units of the resin P-1 in order from left to right in Table 1 and a solution of a polymerization initiator V-601 (manufactured by FUJIFILM Wako Pure Chemical Corporation, 2.17 g) dissolved in 105.0 g of cyclohexanone were added dropwise thereto over 6 hours. After completion of the dropwise addition, the reaction was further performed at 80° C. for 2 hours. The reaction liquid was allowed to cool and was then added dropwise to a liquid mixture of methanol and water over 20 minutes. A powder precipitated by the dropwise addition was then collected by filtration and was dried to produce the resin P-1 (33.6 g). The compositional ratio (mole ratio) of the repeating units determined by a nuclear magnetic resonance (NMR) method was 50/25/25. The resin P-1 had a weight-average molecular weight of 18,000 based on polystyrene standards and a polydispersity (PDI₀) of 2.1.

### [Specific Photoacid Generator]

The structures of specific photoacid generators (D-1 to D-7) in Table 3 are shown below.

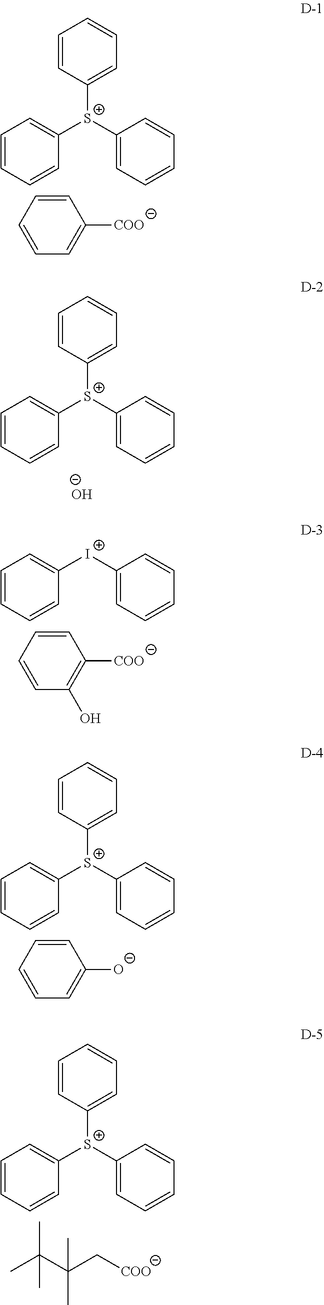

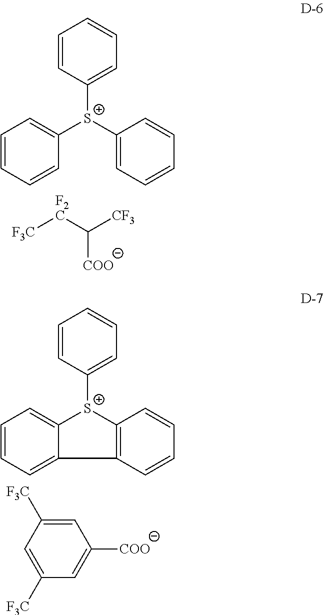

[Other Additives] The structures of other additives (E-1 to E-3) in Table 3 are shown below.

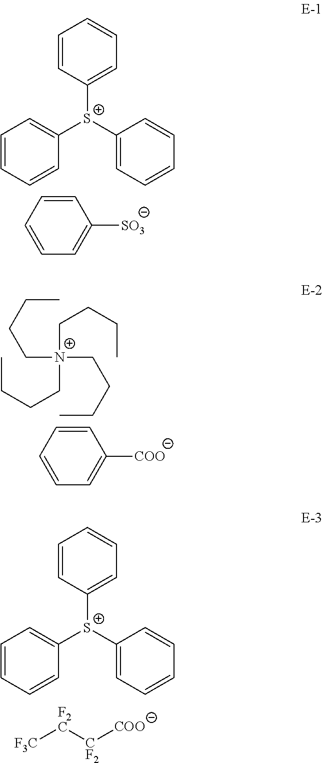

[Solvent] the solvents in Table 3 are described below.
SL-1: Propylene glycol monomethyl ether acetate (PGMEA)
SL-2: Propylene glycol monomethyl ether (PGME)
SL-3: Cyclohexanone
SL-4: γ-butyrolactone
SL-5: Ethyl lactate
SL-6: Diacetone alcohol

### [Developer and Rinse Liquid]

The developers and the rinse liquid in Table 4 are described below.
SD-1: Butyl acetate
SD-2: Isoamyl butyrate:n-octane=90:10 (mass ratio)
SD-3: Butyl acetate:n-undecane=90:10 (mass ratio)

Table 2 shows the physical properties of organic solvents used as developers and rinse liquids. The “Boiling point” in Table 2 means a boiling point at 1 atm (760 mmHg).

C log P values in Table 2 are C log P values calculated using the program C LOG P v4.82, as described above.

TABLE 2

| Organic solvent | Boiling point | ClogP |
|---|---|---|
| Butyl acetate | 126° C. | 1.77 |
| Isoamyl butyrate | 178° C. | 3.23 |
| n-octane | 125° C. | 4.93 |
| n-undecane | 196° C. | 6.51 |

Various components shown in Table 3 were mixed. The resulting liquid mixture was then filtered through a polyethylene filter with a pore size of 0.03 μm to prepare a resin composition (resist composition).

In Table 3, “Repeating unit (A)” indicates a repeating unit having the group represented by the formula (IV), and “Repeating unit (B)” indicates a repeating unit having a carboxy group. “PAG (D)” refers to the specific photoacid generator. “C log P” in the column “PAG (D)” refers to the C log P value of a compound formed by bonding of a proton to an anion included in the specific photoacid generator. “C log P” in the column of “Another additive” indicates the C log P value of a compound formed by bonding of a proton to an anion included in E-1 to E-3.

“Content (% by mass)” in Table 3 represents each component content (% by mass) based on the total solid content of the resist composition.

In Table 3, “Amount in resist solid component (mmol/g)” represents the amount of the repeating unit (A), the repeating unit (B), or PAG (D) (specific photoacid generator) based on the total solid content of the resist composition.

In Table 3, “(A)+(B)” represents the total amount of the amount of the repeating unit (A) based on the total solid content of the resist composition and the amount of the repeating unit (B) based on the total solid content of the resist composition.

The concentration of solid contents of each resist composition was appropriately adjusted for application at a film thickness shown in Table 4 described later. A solid component means all components other than solvents. The resulting resist compositions were used in Examples and Comparative Examples.

TABLE 3

| | Resin (C) | | | | PAG (D) | | | Another |
|---|---|---|---|---|---|---|---|---|
| Resist | | Content | Repeating | Repeating | | Content | | additive |
| composition | Type | (mass %) | unit (A) | unit (B) | Type | (mass %) | ClogP | Type |
| R-1 | P-1 | 84.6% | M-13 | — | D-1 | 15.4% | 1.89 | — |
| R-2 | P-2 | 88.8% | M-13 | — | D-2 | 11.2% | −1.38 | — |
| R-3 | P-3 | 85.7% | M-13 | — | D-4 | 14.3% | 1.48 | — |
| R-4 | P-4 | 83.3% | M-13 | — | D-3 | 16.7% | 2.08 | — |
| R-5 | P-5 | 84.6% | M-13 | M-5 | D-1 | 15.4% | 1.89 | — |
| R-6 | P-6 | 84.6% | — | M-14 | D-1 | 15.4% | 1.89 | — |
| R-7 | P-7 | 96.9% | M-7 | M-14 | D-1 | 3.1% | 1.89 | — |
| R-8 | P-8 | 69.2% | M-13 | M-8 | D-2 | 30.8% | −1.38 | — |
| R-9 | P-9 | 88.8% | M-13 | M-5 | D-2 | 11.2% | −1.38 | — |
| R-10 | P-10 | 84.6% | M-13 | M-9 | D-1 | 15.4% | 1.89 | — |
| R-11 | P-11 | 84.6% | M-13 | — | D-1 | 15.4% | 1.89 | — |
| R-12 | P-1 | 83.2% | M-13 | — | D-5 | 16.8% | 2.99 | — |
| R-13 | P-1 | 79.7% | M-13 | — | D-6 | 20.3% | 2.53 | — |
| R-14 | P-1 | 79.3% | M-13 | — | D-7 | 20.7% | 3.88 | — |
| R-15 | P-12 | 84.6% | — | — | D-1 | 15.4% | 1.89 | — |
| R-16 | P-13 | 83.2% | M-13 | M-5 | — | — | — | E-1 |
| R-17 | P-13 | 85.5% | M-13 | M-5 | — | — | — | E-2 |
| R-18 | P-1 | 80.9% | M-13 | — | — | — | — | E-3 |

| | | | | Amount in resist solid | | | |
|---|---|---|---|---|---|---|---|
| | Another additive | | Solvent | component (mmol/g) | | | |
| Resist | Content | | (mass | Repeating | Repeating | (A) + | PAG |
| composition | (mass %) | ClogP | ratio) | unit (A) | unit (B) | (B) | (D) |
| R-1 | — | — | SL-1/SL-2 = | 1.66 | — | 1.66 | 0.40 |
| | | | 80/20 | | | | |
| R-2 | — | — | SL-1/SL-2/SL-3 = | 0.27 | — | 0.27 | 0.40 |
| | | | 60/20/20 | | | | |
| R-3 | — | — | SL-1/SL-2/SL-5 = | 1.68 | — | 1.68 | 0.40 |
| | | | 30/20/50 | | | | |
| R-4 | — | — | SL-3 = | 2.09 | — | 2.09 | 0.40 |
| | | | 100 | | | | |
| R-5 | — | — | SL-1 = | 0.21 | 0.14 | 0.35 | 0.40 |
| | | | 100 | | | | |
| R-6 | — | — | SL-1/SL-6 = | — | 1.83 | 1.83 | 0.40 |
| | | | 20/80 | | | | |
| R-7 | — | — | SL-1/SL-2/SL-4 = | 1.22 | 1.22 | 2.44 | 0.08 |
| | | | 80/15/5 | | | | |
| R-8 | — | — | SL-1/SL-2 = | 0.75 | 1.12 | 1.87 | 1.10 |
| | | | 60/40 | | | | |
| R-9 | — | — | SL-1/SL-2 = | 2.38 | 0.59 | 2.97 | 0.40 |
| | | | 80/20 | | | | |
| R-10 | — | — | SL-1/SL-2 = | 1.89 | 0.63 | 2.52 | 0.40 |
| | | | 80/20 | | | | |
| R-11 | — | — | SL-1/SL-2 = | 1.51 | — | 1.51 | 0.40 |
| | | | 80/20 | | | | |
| R-12 | — | — | SL-1/SL-2 = | 1.63 | — | 1.63 | 0.40 |
| | | | 80/20 | | | | |
| R-13 | — | — | SL-1/SL-2 = | 1.56 | — | 1.56 | 0.40 |
| | | | 80/20 | | | | |
| R-14 | — | — | SL-1/SL-2 = | 1.56 | — | 1.56 | 0.40 |
| | | | 80/20 | | | | |
| R-15 | — | — | SL-1/SL-2 = | — | — | — | 0.40 |
| | | | 80/20 | | | | |
| R-16 | 16.8% | −0.65 | SL-1/SL-2 = | 1.37 | 1.10 | 2.47 | — |
| | | | 80/20 | | | | |
| R-17 | 14.5% | 1.89 | SL-1/SL-2 = | 1.41 | 1.13 | 2.54 | — |
| | | | 80/20 | | | | |
| R-18 | 19.1% | 3.03 | SL-1/SL-2 = | 1.59 | — | 1.59 | — |
| | | | 80/20 | | | | |

### [Method for Evaluating Requirement 3]

### [PDIₘₐₓ Evaluation in EUV Exposure]

A composition for forming an underlayer film SHB-A940 (manufactured by Shin-Etsu Chemical Co., Ltd.) was applied to a silicon wafer and was baked at 205° C. for 60 seconds to form an underlayer film with a thickness of 20 nm. A resist composition shown in Table 3 was applied to the underlayer film to form a resist film under the conditions (Film thickness and PreBake) shown in Table 4. Thus, the silicon wafer having the resist film was formed.

Using an EUV scanner NXE3300 (NA0.33) manufactured by ASML, the silicon wafer having the resist film formed by the above procedure was subjected to open-frame exposure under irradiation conditions under which Mw₀ of a product produced by cleavage of the resin (C) was half, one-third, one-fourth, or one-fifth.

The silicon wafer after the exposure was immersed in N-methylpyrrolidone to extract a resist component. Using the extract as a sample, the weight-average molecular weight, the number-average molecular weight, and the polydispersity of the product produced by cleavage of the resin (C) were measured by GPC under the above conditions to calculate PDI₂ to PDI₅ and PDIₘₐₓ described above.

When the relationship of the following formula (1) holds between the calculated PDIₘₐₓ and PDI₀, the resist composition satisfies the requirement 3:

PDIₘₐₓ<1.3×PDI₀ Formula (1)

### [Method for Evaluating Requirement 4]

[Measurement of Dissolution Rates DR₁ and DR₂ of Resist Film]

A composition for forming an underlayer film ARC29SR (manufactured by Nissan Chemical Industries, Ltd.) was applied to a silicon wafer and was baked at 205° C. for 60 seconds to form an underlayer film with a thickness of 60 nm. A resist composition shown in Table 3 was applied to the underlayer film and was baked at 80° C. for 60 seconds to form a resist film with a thickness of 40 nm. The thickness was measured with an ellipsometric thickness measurement apparatus. Thus, the silicon wafer having the resist film was formed.

The silicon wafer having the resist film produced by the above procedure was immersed in butyl acetate for 600 seconds and was then rotated at a rotational speed of 4000 rpm for 30 seconds. The thickness (FT₁) of the resist film after development was measured again with the ellipsometric thickness measurement apparatus, and the dissolution rate DR₁ of the resist film was calculated using the following formula (A):

DR₁=(40−FT₁)/600(nm/s) Formula (A)

The thickness (FT₂) of the resist film after development was measured in the same manner except that the baking temperature after application of the resist composition was changed to 130° C., and the dissolution rate DR₂ of the resist film was calculated using the following formula (B):

DR₂=(40−FT₂)/600(nm/s) Formula (B)

When the relationship of the following formula (2) holds between DR₁ and DR₂, the resist composition satisfies the requirement 4:

DR₁>1.1×DR₂ Formula (2)

### [Pattern Formation and Evaluation]

### [Pattern Formation by EUV Exposure]

A composition for forming an underlayer film SHB-A940 (manufactured by Shin-Etsu Chemical Co., Ltd.) was applied to a silicon wafer and was baked at 205° C. for 60 seconds to form an underlayer film with a thickness of 20 nm. A resist composition shown in Table 3 was applied to the underlayer film to form a resist film under the conditions (Film thickness and PreBake) shown in Table 4. Thus, the silicon wafer having the resist film was formed.

The silicon wafer having the resist film formed by the above procedure was subjected to pattern irradiation using an EUV scanner NXE3300 (NA0.33, σ0.9/0.7, dipole illumination) manufactured by ASML. A mask with a line size of 20 nm and line:space=1:1 was used as a reticle. A line and space pattern with a pitch of 40 nm was then formed, only if stated, by baking (post exposure bake; PEB) under the conditions shown in Table 4 and then development by paddling with the developer shown in Table 4 for 30 seconds and, only if stated, by rinsing with the rinse liquid shown in Table 4 for 10 seconds while rotating the wafer at a rotational speed of 1000 rpm, and then rotating the wafer at a rotational speed of 4000 rpm for 30 seconds.

### [Optimum Exposure Amount]

The line width of a line and space pattern was measured with the critical dimension scanning electron microscope (SEM (CG-4100 manufactured by Hitachi High-Technologies Corporation)) while changing the exposure amount, and the exposure amount at a line width of 20 nm was determined as an optimum exposure amount (mJ/cm²).

### [Depth of Focus (DOF Evaluation)]

Using the critical dimension scanning electron microscope (CG-4100 manufactured by Hitachi High-Technologies Corporation), the line width of a line and space pattern was measured at the optimum exposure amount while changing the focal depth, and the focal depth range at which the line width achieved 20±2 nm was defined as DOF (nm). It is desirable that this value be large because the tolerance of the focal shift is large.

### [Results]

Table 4 shows the evaluation results.

TABLE 4

| | Resist application | | | PEB and development | | | | | |
|---|---|---|---|---|---|---|---|---|---|
| | conditions | | | conditions | | | | | |
| | | Film | | | | Rinse | Performance evaluation | | |
| | Resist | thickness (nm) | PreBake | PEB | Developer | liquid | PDI₀ | PDI₂ | PDI₃ |
| Example 1 | R-1 | 40 | 120° C./ | 120° C./ | SD-1 | — | 2.1 | 2.1 | 2.3 |
| Example 2 | R-2 | 40 | 120° C./ | — | SD-1 | — | 2.1 | 2.4 | 2.5 |
| Example 3 | R-3 | 40 | 100° C./ | 120° C./ | SD-1 | — | 2.1 | 2.3 | 2.4 |
| Example 4 | R-4 | 45 | 120° C./ | 100° C./ | SD-1 | — | 2.1 | 2.5 | 2.5 |
| Example 5 | R-5 | 35 | 100° C./ | 120° C./ | SD-1 | — | 1.8 | 2.0 | 1.9 |
| Example 6 | R-6 | 40 | 130° C./ | 120° C./ | SD-1 | — | 1.6 | 1.7 | 1.6 |
| Example 7 | R-7 | 40 | 80° C./ | 100° C./ | SD-1 | — | 2.1 | 2.4 | 2.5 |
| Example 8 | R-8 | 45 | 120° C./ | 120° C./ | SD-1 | — | 2.1 | 2.1 | 2.2 |
| Example 9 | R-9 | 40 | 80° C./ | 120° C./ | SD-2 | — | 1.6 | 1.6 | 1.6 |
| Example 10 | R-10 | 40 | 120° C./ | 120° C./ | SD-1 | SD-3 | 1.6 | 1.7 | 1.6 |
| Example 11 | R-11 | 40 | 120° C./ | 120° C./ | SD-1 | — | 2.1 | 2.5 | 2.9 |
| Example 12 | R-12 | 40 | 120° C./ | 120° C./ | SD-1 | — | 2.1 | 2.1 | 2.3 |
| Example 13 | R-13 | 40 | 120° C./ | 120° C./ | SD-1 | — | 2.1 | 2.1 | 2.3 |
| Example 14 | R-14 | 40 | 120° C./ | 120° C./ | SD-1 | — | 2.1 | 2.1 | 2.3 |
| Comparative | R-15 | 35 | 100° C./ | 120° C./ | SD-1 | — | 2.1 | 2.5 | 2.6 |
| example 1 | | | | | | | | | |
| Comparative | R-16 | 40 | 120° C./ | 120° C./ | SD-1 | — | 2.1 | 2.8 | 3.1 |
| example 2 | | | | | | | | | |
| Comparative | R-17 | 40 | 120° C./ | 120° C./ | SD-1 | — | 2.1 | 2.2 | 2.3 |
| example 3 | | | | | | | | | |
| Comparative | R-18 | 40 | 120° C./ | 120° C./ | SD-1 | — | 2.1 | 2.4 | 2.3 |
| example 4 | | | | | | | | | |

| | Performance evaluation | | | | | | | |
|---|---|---|---|---|---|---|---|---|
| | | | | Formula | DR₁ | DR₂ | Formula | DOF |
| | PDI₄ | PDI₅ | PDIₘₐₓ | (1) | (nm/s) | (nm/s) | (2) | (nm) |
| Example 1 | 2.2 | 2.1 | 2.3 | satisfied | 0.0024 | 0.0017 | satisfied | 60 |
| Example 2 | 2.5 | 2.3 | 2.5 | satisfied | 0.0023 | 0.0017 | satisfied | 55 |
| Example 3 | 2.2 | 2.2 | 2.4 | satisfied | 0.0027 | 0.0019 | satisfied | 65 |
| Example 4 | 2.3 | 2.1 | 2.5 | satisfied | 0.0033 | 0.0027 | satisfied | 70 |
| Example 5 | 1.8 | 1.8 | 2.0 | satisfied | 0.0040 | 0.0031 | satisfied | 75 |
| Example 6 | 1.6 | 1.5 | 1.7 | satisfied | 0.0045 | 0.0035 | satisfied | 80 |
| Example 7 | 2.5 | 2.1 | 2.5 | satisfied | 0.0050 | 0.0048 | not | 55 |
| | | | | | | | satisfied | |
| Example 8 | 2.1 | 2.0 | 2.2 | satisfied | 0.0028 | 0.0022 | satisfied | 55 |
| Example 9 | 1.6 | 1.6 | 1.6 | satisfied | 0.0029 | 0.0025 | satisfied | 85 |
| Example 10 | 1.6 | 1.6 | 1.7 | satisfied | 0.0045 | 0.0033 | satisfied | 90 |
| Example 11 | 2.7 | 2.4 | 2.9 | not | 0.0045 | 0.0033 | satisfied | 50 |
| | | | | satisfied | | | | |
| Example 12 | 2.2 | 2.1 | 2.3 | satisfied | 0.0050 | 0.0040 | satisfied | 55 |
| Example 13 | 2.4 | 2.1 | 2.4 | satisfied | 0.0060 | 0.0050 | satisfied | 60 |
| Example 14 | 2.2 | 2.1 | 2.3 | satisfied | 0.0055 | 0.0045 | satisfied | 60 |
| Comparative | 2.4 | 2.3 | 2.6 | satisfied | 0.0021 | 0.0020 | not | 10 |
| example 1 | | | | | | | satisfied | |
| Comparative | 2.8 | 2.7 | 3.1 | not | 0.0032 | 0.0030 | not | 10 |
| example 2 | | | | satisfied | | | satisfied | |
| Comparative | 2.3 | 2.2 | 2.3 | satisfied | 0.0060 | 0.0040 | satisfied | 5 |
| example 3 | | | | | | | | |
| Comparative | 2.2 | 2.1 | 2.4 | satisfied | 0.0060 | 0.0058 | not | 5 |
| example 4 | | | | | | | satisfied | |

The results in Table 4 showed that a resist composition according to the present invention had desired advantages.

A comparison between Example 1 and Example 11 shows that a resist composition satisfying the requirement 3 has higher DOF performance.

A comparison between Example 1 and Example 7 shows that a resist composition satisfying the requirement 4 has higher DOF performance.

A comparison between Examples 1, 3 to 6, and 9 and 10 and Example 2 shows that the total amount of the repeating unit (A) and the repeating unit (B) equal to or higher than 0.30 mmol/g based on the total solid content of the resist composition results in higher DOF performance.

A comparison between Example 1 and Examples 3 and 4 shows that the resin (C) with a weight-average molecular weight (Mw₀) of 20,000 or more (preferably 30,000 or more) has higher DOF performance.

A comparison between Example 4 and Examples 5 and 6 shows that the resin (C) with a polydispersity (PDI₀) of 2.0 or less (preferably 1.7 or less) has higher DOF performance.

A comparison between Example 1 and Examples 7 and 8 shows that the specific photoacid generator content in the range of 0.10 to 1.00 mmol/g based on the total solid content of the resist composition results in higher DOF performance.

A comparison between Example 6 and Example 9 shows that the developer or rinse liquid including two or more organic solvents results in higher DOF performance.

A comparison between Example 9 and Example 10 shows that the developer or rinse liquid including the first organic solvent and the second organic solvent, the first organic solvent with a higher boiling point than the second organic solvent, and the first organic solvent with a higher C log P value than the second organic solvent result in higher DOF performance.

What is claimed is:

1. An actinic ray-sensitive or radiation-sensitive resin composition comprising:
a resin that includes a repeating unit represented by a formula (I) and a repeating unit represented by a formula (II) and has a main chain that is cleaved by exposure; and
an ionic compound represented by a formula (III),
wherein the resin satisfies at least one of a requirement 1 or a requirement 2:
requirement 1: at least one repeating unit selected from the group consisting of the repeating unit represented by the formula (I) and the repeating unit represented by the formula (II) has a group represented by a formula (IV) or a carboxy group, and
requirement 2: the resin further includes another repeating unit different from both the repeating unit represented by the formula (I) and the repeating unit represented by the formula (II), and the other repeating unit has the group represented by the formula (IV) or a carboxy group, 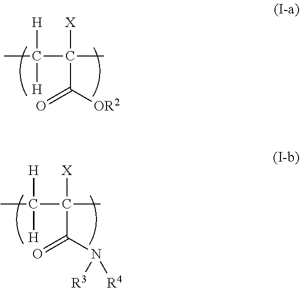
in the formula (I),
X denotes a halogen atom, and
Y denotes a group represented by a formula (Y-1) or a group represented by a formula (Y-2),
in the formula (II),
R¹ denotes an alkyl group optionally having a substituent, and
Ar denotes a monovalent aromatic group optionally having a substituent, 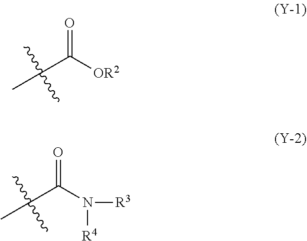
in the formula (Y-1),
R² denotes a hydrogen atom or a monovalent organic group, and a wavy line portion represents a binding position,
in the formula (Y-2),
R³ and R⁴ each independently denote a hydrogen atom or a monovalent organic group, and a wavy line portion represents a binding position, 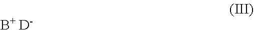
in the formula (III),
B⁺ denotes a sulfonium cation or an iodonium cation, and
D⁻ denotes a hydroxide ion, an anion formed by dissociation of a proton from a hydroxy group in a compound having the hydroxy group, or an anion formed by dissociation of a proton from a carboxy group in a compound having the carboxy group, provided that when D⁻ is an anion formed by dissociation of a proton from a carboxy group in a specific compound having the carboxy group and not including an aromatic ring, the specific compound has a C log P value of 3.00 or less, and 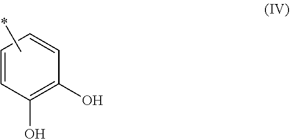
in the formula (IV), * denotes a binding position.

2. The actinic ray-sensitive or radiation-sensitive resin composition according to claim 1, wherein a requirement 3 is satisfied:
requirement 3: when a polydispersity of the resin in a resist film formed using the actinic ray-sensitive or radiation-sensitive resin composition is denoted by PDI₀,
when the resist film is subjected to exposure treatment under an irradiation condition under which a weight-average molecular weight of a product produced by cleavage of the resin in the resist film is half a weight-average molecular weight of the resin, and a polydispersity of the product produced by cleavage of the resin is denoted by PDI₂,
when the resist film is subjected to exposure treatment under an irradiation condition under which the weight-average molecular weight of the product produced by cleavage of the resin in the resist film is one-third the weight-average molecular weight of the resin, and the polydispersity of the product produced by cleavage of the resin is denoted by PDI₃,
when the resist film is subjected to exposure treatment under an irradiation condition under which the weight-average molecular weight of the product produced by cleavage of the resin in the resist film is one-fourth the weight-average molecular weight of the resin, and the polydispersity of the product produced by cleavage of the resin is denoted by PDI₄,
when the resist film is subjected to exposure treatment under an irradiation condition under which the weight-average molecular weight of the product produced by cleavage of the resin in the resist film is one-fifth the weight-average molecular weight of the resin, and the polydispersity of the product produced by cleavage of the resin is denoted by PDI₅, and
when a highest value among PDI₂ to PDI₅ is denoted by PDIₘₐₓ, a relationship of a formula (1) is satisfied:
PDIₘₐₓ<1.3×PDI₀ Formula (1)

3. The actinic ray-sensitive or radiation-sensitive resin composition according to claim 1, wherein a requirement 4 is satisfied:
requirement 4: when a dissolution rate in butyl acetate of a resist film formed by applying the actinic ray-sensitive or radiation-sensitive resin composition to a silicon wafer and heating the actinic ray-sensitive or radiation-sensitive resin composition at 80° C. for 60 seconds is denoted by DR₁, and
when a dissolution rate in butyl acetate of a resist film formed by applying the actinic ray-sensitive or radiation-sensitive resin composition to a silicon wafer and heating the actinic ray-sensitive or radiation-sensitive resin composition at 130° C. for 60 seconds is denoted by DR₂, a relationship of a formula (2) is satisfied:
DR₁>1.1×DR₂ Formula (2)

4. The actinic ray-sensitive or radiation-sensitive resin composition according to claim 1, wherein a total amount of the repeating unit having the group represented by the formula (IV) and the repeating unit having the carboxy group in the resin is 0.30 mmol/g or more based on a total solid content of the actinic ray-sensitive or radiation-sensitive resin composition.

5. The actinic ray-sensitive or radiation-sensitive resin composition according to claim 1, wherein the resin has a weight-average molecular weight of 20,000 or more.

6. The actinic ray-sensitive or radiation-sensitive resin composition according to claim 1, wherein the resin has a weight-average molecular weight of 30,000 or more.

7. The actinic ray-sensitive or radiation-sensitive resin composition according to claim 1, wherein the resin has a polydispersity of 2.0 or less.

8. The actinic ray-sensitive or radiation-sensitive resin composition according to claim 1, wherein the resin has a polydispersity of 1.7 or less.

9. The actinic ray-sensitive or radiation-sensitive resin composition according to claim 1, wherein an ionic compound content ranges from 0.10 to 1.00 mmol/g based on the total solid content of the actinic ray-sensitive or radiation-sensitive resin composition.

10. A resist film formed by using the actinic ray-sensitive or radiation-sensitive resin composition according to claim 1.

11. A pattern forming method comprising:
a step 1 of forming a resist film on a substrate using the actinic ray-sensitive or radiation-sensitive resin composition according to claim 1;
a step 2 of exposing the resist film; and
a step 3 of developing the exposed resist film using a developer including an organic solvent to form a pattern.

12. The pattern forming method according to claim 11, further comprising a step 4 of washing the pattern using a rinse liquid including an organic solvent after the step 3.

13. The pattern forming method according to claim 11, wherein
when the pattern forming method does not have the step 4 of washing the pattern using the rinse liquid including the organic solvent after the step 3, the developer includes two or more organic solvents, and
when the pattern forming method has the step 4 of washing the pattern using the rinse liquid including the organic solvent after the step 3, at least one of the developer or the rinse liquid includes two or more organic solvents.

14. The pattern forming method according to claim 13, wherein
the two or more organic solvents include a first organic solvent and a second organic solvent,
the first organic solvent has a higher boiling point than the second organic solvent, and
the first organic solvent has a higher C log P value than the second organic solvent.

15. A method for producing an electronic device, comprising the pattern forming method according to claim 11.

16. An electronic device produced by the method for producing an electronic device according to claim 15.
